(19) United States
(12) Patent Application Publication
(10) Pub. No.: US 2025/0287808 A1
(43) Pub. Date: Sep. 11, 2025

(54) DISPLAY DEVICE

(71) Applicant: Samsung Display Co., LTD., Yongin-si, Gyeonggi-do (KR)

(72) Inventors: Sun Kwun SON, Yongin-si, Gyeonggi-do (KR); Dong Hee SHIN, Yongin-si, Gyeonggi-do (KR); Na Hyeon CHA, Yongin-si, Gyeonggi-do (KR)

(73) Assignee: Samsung Display Co., LTD., Yongin-si, Gyeonggi-do (KR)

(21) Appl. No.: 18/894,750

(22) Filed: Sep. 24, 2024

(30) Foreign Application Priority Data
Jan. 16, 2024 (KR) 10-2024-0006427

(51) Int. Cl. H10K 59/35; H10K 50/19; H10K 59/131; H10K 59/38

(52) U.S. Cl. CPC H10K 59/353; H10K 59/131; H10K 59/351; H10K 59/38; H10K 50/19

(57) ABSTRACT

A display device includes a pixel electrode disposed on a substrate; a light emitting layer disposed on the pixel electrode; a common electrode disposed on the light emitting layer; and a color filter part disposed on the common electrode, the color filter part of a first unit pixel comprises a first color filter, a second color filter and a third color filter having a substantially fan shape, the first unit pixel comprises a first pixel area, a second pixel area, a third pixel area and a fourth pixel area, and a center of an arc of the first color filter, a center of an arc of the second color filter and a center of an arc of the third color filter are disposed in different pixel areas.

### CROSS-REFERENCE TO RELATED APPLICATION(S)

This application claims priority to and benefits of Korean Patent Application No. 10-2024-0006427 under 35 U.S.C. § 119, filed on Jan. 16, 2024, in the Korean Intellectual Property Office, the entire contents of which are incorporated herein by reference.

### BACKGROUND

### 1. Technical Field

The disclosure relates to a display device, and, to a display device which can improve image quality by minimizing a color fringing phenomenon.

### 2. Description of the Related Art

Display devices are becoming increasingly important with the development of multimedia. Accordingly, various display devices such as liquid crystal display devices (LCDs) and organic light emitting diode display devices (OLEDs) are being developed.

Of the display devices, a self-light emitting display device may include a self-light emitting element such as an organic light emitting diode. The self-light emitting element may include two electrodes facing each other and a light emitting layer between the two electrodes. In case that the self-light emitting element is an organic light emitting diode, electrons and holes provided from the two electrodes may be recombined in the light emitting layer to generate excitons. As the generated excitons change from an excited state to a ground state, light may be emitted.

A display device may include a color conversion element for realizing color by receiving light from an organic light emitting diode. For example, the color conversion element may receive blue light from the organic light emitting diode and emit light of blue, green and red, so that an image having various colors can be viewed. The color conversion element may be disposed in the form of a separate substrate in the display device or may be directly integrated with elements in the display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device which can improve image quality by minimizing a color fringing phenomenon.

According to an embodiment, a display device may include a pixel electrode disposed on a substrate; a light emitting layer disposed on the pixel electrode; a common electrode disposed on the light emitting layer; and a color filter part disposed on the common electrode, wherein the color filter part of a first unit pixel comprises a first color filter, a second color filter and a third color filter having a substantially fan shape, the first unit pixel comprises a first pixel area, a second pixel area, a third pixel area and a fourth pixel area, and a center of an arc of the first color filter, a center of an arc of the second color filter and a center of an arc of the third color filter are disposed in different pixel areas.

In an embodiment, the center of the arc of the first color filter, the center of the arc of the second color filter, and the center of the arc of the third color filter may be respectively disposed in any three pixel areas among the first pixel area, the second pixel area, the third pixel area and the fourth pixel area.

In an embodiment, the center of the arc of the first color filter, the center of the arc of the second color filter, and the center of the arc of the third color filter may not be disposed in any one of the first pixel area, the second pixel area, the third pixel area and the fourth pixel area.

In an embodiment, a second unit pixel adjacent to the first unit pixel in one direction may comprise a first pixel area, a second pixel area, a third pixel area and a fourth pixel area, a color filter part disposed in the second unit pixel may comprise a first color filter, a second color filter and a third color filter having a substantially fan shape, and the color filter part of the second unit pixel has a different shape from the color filter part of the first unit pixel in plan view.

In an embodiment, the color filter part of the second unit pixel may have a shape rotated at a selectable angle with respect to the color filter part of the first unit pixel.

In an embodiment, the color filter part of the second unit pixel may have a shape rotated about 90 degrees or about 180 degrees clockwise or counterclockwise with respect to the color filter part of the first unit pixel.

In an embodiment, positions of the first color filter, the second color filter and the third color filter included in the color filter part of the second unit pixel may be different from positions of the first color filter, the second color filter and the third color filter included in the color filter part of the first unit pixel.

In an embodiment, the first color filter of the second unit pixel may have a shape rotated at a selectable angle with respect to the first color filter of the first unit pixel.

In an embodiment, the first color filter of the second unit pixel may have a shape rotated about 90 degrees or about 180 degrees clockwise or counterclockwise with respect to the first color filter of the first unit pixel.

In an embodiment, the center of the arc of the first color filter disposed in the first unit pixel and a center of an arc of the first color filter disposed in the second unit pixel may be disposed in different pixel areas.

In an embodiment, in case that an imaginary line connecting the center of the arc of the first color filter disposed in the first unit pixel and a center of the first color filter disposed in the first unit pixel may be defined as a first center line and an imaginary line connecting the center of the arc of the first color filter disposed in the second unit pixel and a center of the first color filter disposed in the second unit pixel may be defined as a second center line, an angle between an imaginary line extending along the first center line and an imaginary line extending along the second center line may be about 90 degrees or about 180 degrees.

In an embodiment, a third unit pixel adjacent to the first unit pixel in the other direction intersecting the one direction may comprise a first pixel area, a second pixel area, a third pixel area and a fourth pixel area, a color filter part disposed in the third unit pixel may comprise a first color filter, a second color filter and a third color filter having a substantially fan shape, and the color filter part of the third unit pixel may have substantially a same shape as the color filter part of the first unit pixel in plan view.

In an embodiment, a pixel defining layer may be disposed on the pixel electrode and defining a drilling area and a light emitting area overlapping the pixel electrode.

In an embodiment, a common voltage line may be disposed on the substrate; and a common connection electrode disposed on the common voltage line and electrically connected to the common voltage line through a contact hole of an insulating layer in the drilling area.

In an embodiment, the light emitting layer may have a drilling hole penetrating the light emitting layer in the drilling area.

In an embodiment, the common electrode may be electrically connected to the common connection electrode through the drilling hole of the light emitting layer.

In an embodiment, the drilling hole may be disposed in an intersection area of the common voltage line and the common connection electrode.

In an embodiment, the common connection electrode may extend in one direction, and the common voltage line may extend in the other direction intersecting the one direction.

In an embodiment, the first unit pixel may be disposed in any one of unit areas surrounded and defined by a plurality of common voltage lines and a plurality of common connection electrodes.

In an embodiment, each of the first pixel area, the second pixel area, the third pixel area and the fourth pixel area may have a substantially triangular shape.

In an embodiment, at least one of the first color filter, the second color filter, and the third color filter may have a central angle of about 120 degrees.

In an embodiment, the pixel electrode of the first unit pixel may comprise a first pixel electrode corresponding to the first color filter and having a substantially fan shape; a second pixel electrode corresponding to the second color filter and having a substantially fan shape; and a third pixel electrode corresponding to the third color filter and having a substantially fan shape.

In an embodiment, a light transmitting part may be disposed between the common electrode and the color filter part.

In an embodiment, the light transmitting part may comprise a first light transmitting part corresponding to the first color filter and having a substantially fan shape;

In an embodiment, a second light transmitting part may correspond to the second color filter and have a substantially fan shape; and a third light transmitting part corresponding to the third color filter and having a substantially fan shape.

In an embodiment, the first color filter may be a color filter which transmits blue light, the second color filter may be a color filter which transmits green light, and the third color filter may be a blue color filter which transmits red light.

However, aspects of the disclosure are not restricted to the ones set forth herein. The above and other aspects of the disclosure will become more apparent to one of ordinary skill in the art to which the disclosure pertains by referencing the detailed description of the disclosure given below.

According to an aspect of the disclosure, there is provided a display device which can improve image quality by minimizing a color fringing phenomenon.

According to another aspect of the disclosure, there is provided a display device including color filters facing an upper edge of a unit pixel group having various colors, thereby minimizing a color fringing phenomenon.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a display device according to an embodiment;

FIG. 2 is a schematic cross-sectional view taken along line X1-X1′ of FIG. 1;

FIG. 3 is a schematic plan view of the display device according to the embodiment;

FIG. 4 is a schematic cross-sectional view of the display device according to the embodiment;

FIG. 5 is an enlarged view of area A1 of FIG. 4;

FIG. 6 is a schematic diagram of an equivalent circuit of a first pixel of the display device according to the embodiment;

FIG. 7 is a schematic plan view of the display device according to the embodiment;

FIG. 8 is a schematic plan view of a color filter member disposed to correspond to each unit pixel of FIG. 7;

FIG. 9 is an array view of the display device according to the embodiment; and

FIG. 10 is a schematic cross-sectional view taken along line X2-X2′ of FIG. 9.

### DETAILED DESCRIPTION OF THE EMBODIMENTS

Advantages and features of the disclosure and methods of accomplishing the same may be understood more readily by reference to the following detailed description of embodiments and the accompanying drawings. The disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the disclosure will also be defined by the appended claims.

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are examples, and the disclosure is not limited to the illustrated details.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the disclosure.

Features of various embodiments of the disclosure may be partially or entirely coupled to or combined with each other, and may be inter-operated and driven in technically various ways. The embodiments may be implemented independently from each other, or may be implemented together.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Hereinafter, embodiments will be described with reference to the accompanying drawings.

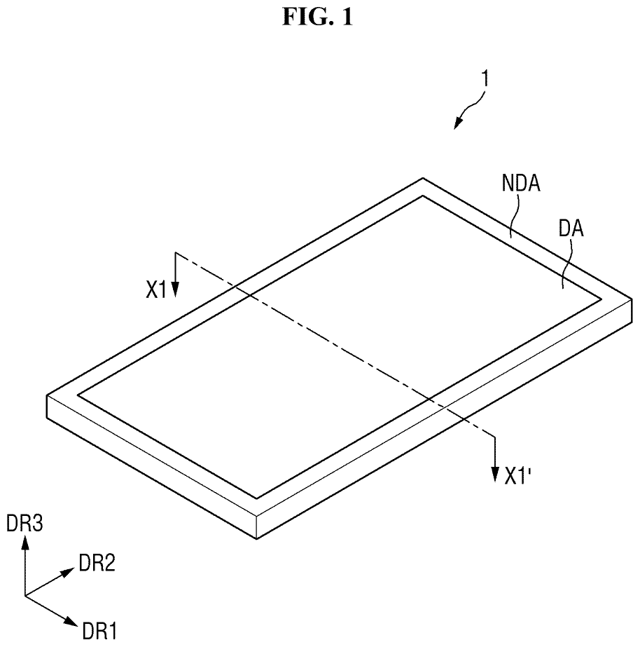

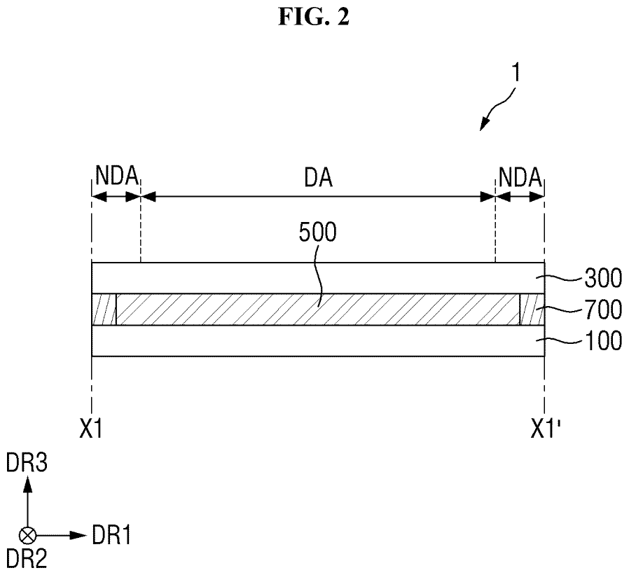

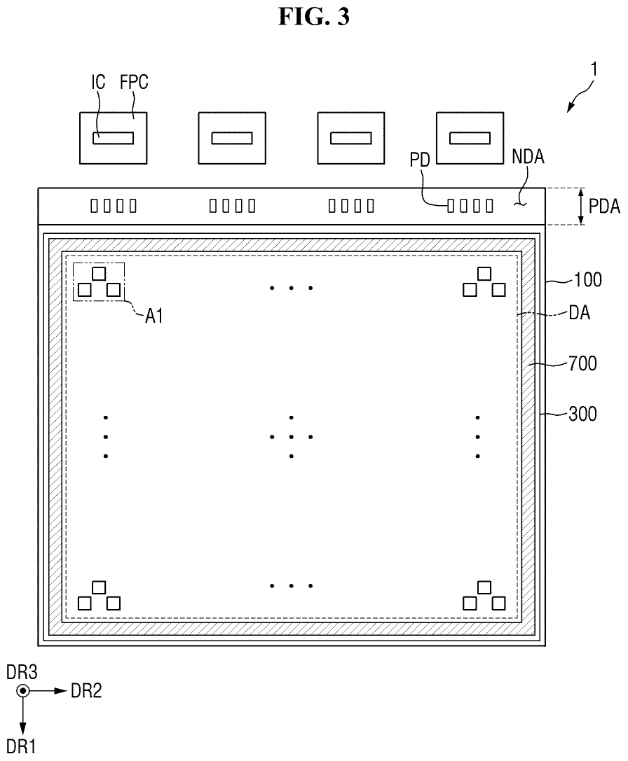

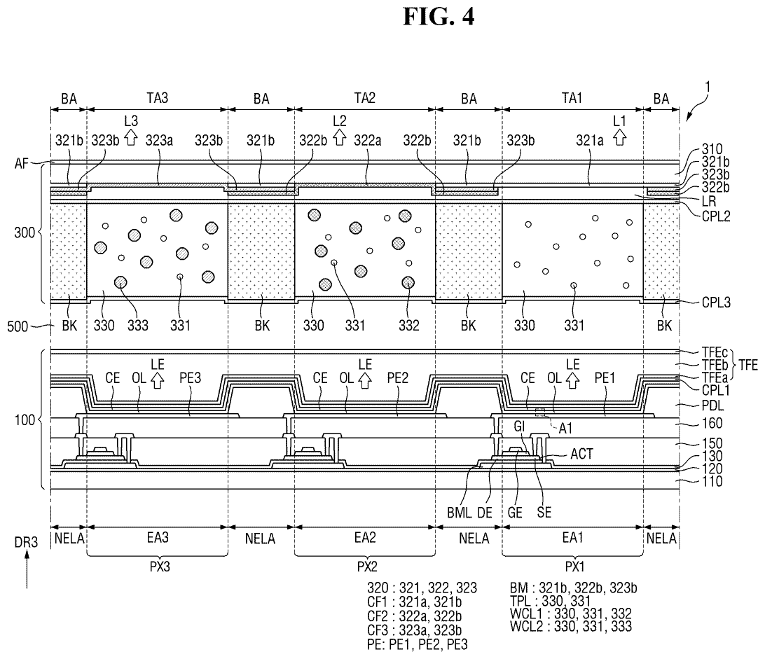

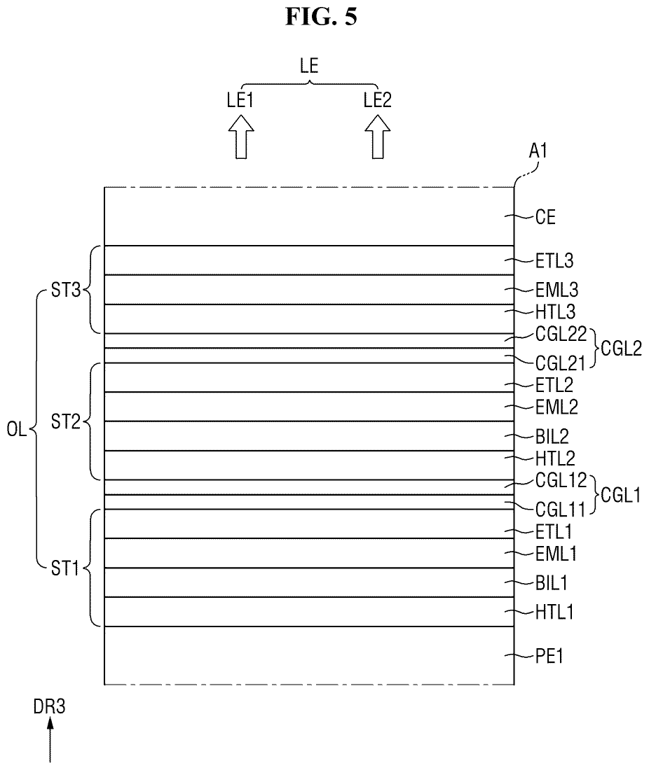

FIG. 1 is a schematic perspective view of a display device 1 according to an embodiment. FIG. 2 is a schematic cross-sectional view taken along line X1-X1′ of FIG. 1. FIG. 3 is a schematic plan view of the display device 1 according to the embodiment. FIG. 4 is a schematic cross-sectional view of the display device 1 according to the embodiment. FIG. 5 is an enlarged view of area A1 of FIG. 4.

Referring to FIGS. 1 and 2, the display device 1 according to the embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). By way of example, the display device 1 according to the embodiment may be applied as a display unit of a television, a laptop computer, a monitor, a billboard, or an Internet of things (IoT) device. However, these are presented as examples, and the display device 1 according to the embodiment may also be employed in other electronic devices within the spirit and the scope of the disclosure.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a vertical direction in the drawing, the second direction DR2 refers to a horizontal direction in the drawing, and the third direction DR3 refers to an up-down direction in the drawing, for example, a thickness direction. In the following specification, unless otherwise specified, a “direction” may refer to both directions extending to both sides along the direction. In case that it is necessary to distinguish both “directions” extending to both sides, one side or a side will be referred to as a “first side in the direction,” and the other side will be referred to as a “second side in the direction.” Based on FIG. 1, a direction in which an arrow is directed will be referred to as the first side, and a direction opposite to the direction will be referred to as the second side.

For ease of description, in referring to surfaces of the display device 1 or each member constituting the display device 1, one surface or a surface facing the first side in a direction in which an image is displayed, for example, in the third direction DR3 will be referred to as an upper surface, and the other surface or another surface opposite the one surface or a surface will be referred to as a lower surface. However, the disclosure is not limited thereto, and the one surface and the other surface or another surface of each member may also be referred to as a front surface and a rear surface or as a first surface and a second surface, respectively. In describing relative positions of the members of the display device 1, the first side in the third direction DR3 may be referred to as an upper side, and the second side in the third direction DR3 may be referred to as a lower side.

The display device 1 has a three-dimensional (3D) shape. For example, the display device 1 may have a rectangular parallelepiped shape or a 3D shape similar to the rectangular parallelepiped shape. In an embodiment, the display device 1 according to the embodiment may have a planar shape similar to a quadrilateral. In other words, the display device 1 according to the embodiment may have a planar shape similar to a quadrilateral having long sides in the first direction DR1 and short sides in the second direction DR2 as illustrated in FIG. 1. However, the disclosure is not limited thereto. For example, in the planar shape of the display device 1 according to the embodiment, each corner where a long side extending in the first direction DR1 meets a short side extending in the second direction DR2 may be rounded with a selectable curvature or may be right-angled. The planar shape of the display device 1 is not limited to a quadrilateral shape but may also be similar to other polygonal shapes, a circular shape, or an oval shape.

The display device 1 may include a display area DA in which a screen is displayed and a non-display area NDA in which a screen is not displayed. In an embodiment, the non-display area NDA may surround edges of the display area DA, but the disclosure is not limited thereto. An image displayed in the display area DA may be viewed by a user from the first side in the third direction DR3 based on FIG. 1.

As illustrated in FIG. 2, the display device 1 may include a light emitting unit 100 and a light transmitting unit 300 facing the light emitting unit 100 and may further include a sealing member 700 bonding the light emitting unit 100 and the light transmitting unit 300 together and a filler 500 filling a space between the light emitting unit 100 and the light transmitting unit 300.

The light emitting unit 100 may include elements and circuits for displaying an image, for example, a pixel circuit such as a switching element, a pixel defining layer PDL defining a light emitting area and a non-light emitting area, which will be described later, in the display area DA, and a self-light emitting element. In an embodiment, the self-light emitting element may include at least one of an organic light emitting diode, a quantum dot light emitting diode, an inorganic material-based micro light emitting diode (for example, micro LED), and an inorganic material-based nano light emitting diode (for example, nano LED). For ease of description, a case where the self-light emitting element is an organic light emitting diode will be described below as an example.

The light transmitting unit 300 may be located (or disposed) on the light emitting unit 100 and may face the light emitting unit 100. In an embodiment, the light transmitting unit 300 may include a color conversion pattern for converting the color of incident light emitted from the light emitting unit 100 and irradiated to the light transmitting unit 300. In an embodiment, the light transmitting unit 300 may include at least any one of a color filter member 320 and a light transmitting member, which will be described later, as the color conversion pattern. In an embodiment, the light transmitting unit 300 may include both the color filter member 320 and the light transmitting member. The light transmitting member may include wavelength conversion shifters and/or light scatterers as will be described later. The light transmitting unit 300 may be referred to as a color conversion element in the claims.

The sealing member 700 may be located between the light emitting unit 100 and the light transmitting unit 300 in the non-display area NDA. The sealing member 700 may be disposed along edges of the light emitting unit 100 and the light transmitting unit 300 in the non-display area NDA to surround the display area DA in plan view. The light emitting unit 100 and the light transmitting unit 300 may be bonded to each other by the sealing member 700.

In an embodiment, the sealing member 700 may be made of an organic material. For example, the sealing member 700 may be made of, but not limited to, epoxy resin. In an embodiment, the sealing member 700 may be applied in the form of a frit including glass or the like within the spirit and the scope of the disclosure.

The filler 500 may be located in the space between the light emitting unit 100 and the light transmitting unit 300 surrounded by the sealing member 700. The filler 500 may fill the space between the light emitting unit 100 and the light transmitting unit 300.

In an embodiment, the filler 500 may be made of a material that can transmit light. In an embodiment, the filler 500 may be made of an organic material. For example, the filler 500 may be made of a silicon-based organic material, an epoxy-based organic material, or a mixture of a silicon-based organic material and an epoxy-based organic material.

Referring to FIG. 3, the display device 1 may further include flexible circuit boards FPC and driving chips IC.

The non-display area NDA of the display device 1 may include a pad area PDA, and connection pads PD may be located in the pad area PDA. The pad area PDA may be defined on the light emitting unit 100. Accordingly, the connection pads PD may be disposed on the light emitting unit 100.

The flexible circuit boards FPC may be connected to the connection pads PD. The flexible circuit boards FPC may electrically connect the light emitting unit 100 to a circuit board that provides signals and power for driving the display device 1.

The driving chips IC may be electrically connected to the circuit board to receive data and signals. In an embodiment, the driving chips IC may be data driving chips IC and may receive a data control signal and image data from the circuit board and generate and output data voltages corresponding to the image data.

In an embodiment, the driving chips IC may be mounted on the flexible circuit boards FPC. For example, the driving chips IC may be mounted on the flexible circuit boards FPC in the form of chips on films (COF).

The data voltages provided from the driving chips IC, the power provided from the circuit board, etc. may be transmitted to pixel circuits of the light emitting unit 100 via the flexible circuit boards FPC and the connection pads PD as will be described later.

Light emitting areas defined in the light emitting unit 100 of the display device 1 and light transmitting areas defined in the light transmitting unit 300 will now be described in more detail.

Light emitting areas may be defined in the light emitting unit 100 of the display device 1 according to the embodiment, and light transmitting areas may be defined in the light transmitting unit 300.

The display area DA and the non-display area NDA defined in the display device 1 may be applied to the light emitting unit 100 and the light transmitting unit 300.

A first light emitting area EA1, a second light emitting area EA2, and a third light emitting area EA3 may be defined in the display area DA of the light emitting unit 100. The first light emitting area EA1, the second light emitting area EA2, and the third light emitting area EA3 may be areas where light generated by light emitting elements of the light emitting unit 100 is emitted to the outside of the light emitting unit 100. A non-light emitting area NELA may be an area where light is not emitted to the outside of the light emitting unit 100. In an embodiment, the non-light emitting area NELA may surround the first light emitting area EA1, the second light emitting area EA2, and the third light emitting area EA3 in the display area DA, but the disclosure is not limited thereto.

In an embodiment, light emitted from the first light emitting area EA1, the second light emitting area EA2 and the third light emitting area EA3 to the outside may be light of a first color. In an embodiment, the light of the first color may be blue light and may have a peak wavelength in the range of about 440 to about 480 nm. Here, the peak wavelength refers to a wavelength at which the intensity of light is maximum.

In an embodiment, the area of the first light emitting area EA1, the area of the second light emitting area EA2, and the area of the third light emitting area EA3 may be substantially the same. However, the disclosure is not limited thereto. For example, the area of the first light emitting area EA1, the area of the second light emitting area EA2, and the area of the third light emitting area EA3 may also be different from each other.

A first light transmitting area TA1, a second light transmitting area TA2, and a third light transmitting area TA3 may be defined in the display area DA of the light transmitting unit 300. The first light emitting area TA1, the second light transmitting area TA2, and the third light emitting area TA3 may be areas through which light generated from the first light emitting area EA1, the second light emitting area EA2, and the third light emitting area EA3 of the light emitting unit 100 is transmitted. A light blocking area BA may be located around the first light transmitting area TA1, the second light transmitting area TA2, and the third light transmitting area TA3 in the display area DA of the light transmitting unit 300. In an embodiment, the light blocking area BA may surround the first light transmitting area TA1, the second light transmitting area TA2, and the third light transmitting area TA3. However, the disclosure is not limited thereto. For example, the light blocking area BA may be located in the non-display area NDA as well as in the display area DA of the light transmitting unit 300.

The first light transmitting area TA1 may correspond to and overlap the first light emitting area EA1, the second light transmitting area TA2 may correspond to and overlap the second light emitting area EA2, and the third light transmitting area TA3 may correspond to and overlap the third light emitting area EA3. In an embodiment, the first light transmitting area TA1 may have substantially the same area as the first light emitting area EA1 to completely overlap the first light emitting area EA1, the second light transmitting area TA2 may have substantially the same area as the second light emitting area EA2 to completely overlap the second light emitting area EA2, and the third light transmitting area TA3 may have substantially the same area as the third light emitting area EA3 to completely overlap the third light emitting area EA3. However, the disclosure is not limited thereto. For example, the first light emitting area TA1 may also have a different area from the first light emitting area EA1, the second light transmitting area TA2 may also have a different area from the second light emitting area EA2, and the third light transmitting area TA3 may also have a different area from the third light emitting area EA3.

The first light transmitting area TA1, the second light transmitting area TA2, and the third light transmitting area TA3 may form one group. One group formed by the first light transmitting area TA1, the second light transmitting area TA2, and the third light transmitting area TA3 may be repeatedly disposed in the display area DA.

As described above, light of the first color emitted from the light emitting unit 100 may be provided to the outside of the display device 1 through the first light transmitting area TA1, the second light transmitting area TA2, and the third light transmitting area TA3. Light emitted from the first light transmitting area TA1 to the outside of the display device 1 may be referred to as first output light, light emitted from the second light transmitting area TA2 to the outside of the display device 1 may be referred to as second output light, and light emitted from the third light transmitting area TA3 to the outside of the display device 1 may be referred to as third output light. In this case, the first output light may be light of the first color, the second output light may be light of a second color, and the third output light may be light of a third color.

In an embodiment, the light of the first color may be blue light having a peak wavelength in the range of about 440 to about 480 nm as described above, and the light of the second color may be green light having a peak wavelength in the range of about 510 to about 550 nm. The light of the third color may be red light having a peak wavelength in the range of about 610 to about 650 nm.

The structure of the display device 1 will now be described in detail.

Referring to FIG. 4, as described above, the display device 1 may include the light emitting unit 100, the light transmitting unit 300 disposed on the light emitting unit 100 to face the light emitting unit 100, and the filler 500 between the light emitting unit 100 and the light transmitting unit 300. For ease of explanation, the light emitting unit 100, the light transmitting unit 300, and the filler 500 will be described below in this order.

The light emitting unit 100 may have a structure in which a first substrate 110, a buffer layer 120, bottom metal layers BML, a first insulating layer 130, active layers ACT, gate electrodes GE, gate insulating layers GI, a second insulating layer 150, source/drain electrodes, a third insulating layer 160, light emitting elements, a pixel defining layer PDL, a first capping layer CPL1, and a thin-film encapsulation layer TFE are sequentially stacked each other to the first side in the third direction DR3.

The first substrate 110 of the light emitting unit 100 may serve as a base of the light emitting unit 100. The first substrate 110 may be made of a light transmitting material. The first substrate 110 may be a glass substrate or a plastic substrate. In case that the first substrate 110 is a plastic substrate, it may have flexibility. In an embodiment, in case that the first substrate 110 is a plastic substrate, it may include, but is not limited to, polyimide.

The buffer layer 120 of the light emitting unit 100 may be disposed on the first substrate 110. The buffer layer 120 may block foreign substances or moisture introduced through the first substrate 110 from entering elements disposed on the buffer layer 120.

In an embodiment, the buffer layer 120 may include an inorganic material such as SiO₂, SiNₓ or SiON and may be formed as a single layer or a multilayer, but the disclosure is not limited thereto.

The bottom metal layers BML of the light emitting unit 100 may be disposed on the buffer layer 120. The bottom metal layers BML may block external light or light emitted from the light emitting elements to be described later from entering the active layers ACT. Accordingly, the bottom metal layers BML can prevent leakage current from being generated due to light in thin-film transistors which will be described later or can reduce the generation of the leakage current.

The bottom metal layers BML may be made of a material that blocks light and has conductivity. In an embodiment, the bottom metal layers BML may include a single material selected from metals such as silver (Ag), nickel (Ni), gold (Au), platinum (Pt), aluminum (Al), copper (Cu), molybdenum (Mo), titanium (Ti) and neodymium (Nd) or may include an alloy of the metals. In an embodiment, the bottom metal layers BML may have a single-layer structure or a multilayer structure. For example, in case that the bottom metal layers BML have a multilayer structure, each of the bottom metal layers BML may be, but is not limited to, a stacked structure of titanium (Ti)/copper (Cu)/indium tin oxide (ITO) or a stacked structure of titanium (Ti)/copper (Cu)/aluminum oxide (Al₂O₃).

In an embodiment, the bottom metal layers BML may correspond to the active layers ACT and overlap the active layers ACT, respectively. In an embodiment, the bottom metal layers BML may be wider than the active layers ACT.

In an embodiment, the bottom metal layers BML may be part of data lines, power supply lines, and lines that electrically connect thin-film transistors not illustrated in the drawing to the thin-film transistors (GE, ACT, DE and SE in FIG. 4) illustrated in the drawing. In an embodiment, the bottom metal layers BML may be made of a material having a lower resistance than those of source electrodes SE and drain electrodes DE.

The first insulating layer 130 of the light emitting unit 100 may be disposed on the bottom metal layers BML. The first insulating layer 130 may electrically insulate the bottom metal layers BML from the active layers ACT. The first insulating layer 130 may cover the bottom metal layers BML.

In an embodiment, the first insulating layer 130 may include, but is not limited to, an inorganic material such as SiO₂, SiNₓ, SION, Al₂O₃, TiO₂, Ta₂O, HfO₂, or ZrO₂.

The active layers ACT of the light emitting unit 100 may be disposed on the first insulating layer 130. The active layers ACT may respectively correspond to the first light emitting area EA1, the second light emitting area EA2, and the third light emitting area EA3 in the display area DA of the light emitting unit 100. The active layers ACT may respectively overlap the bottom metal layers BML, thereby suppressing generation of a photocurrent in the active layers ACT.

The active layers ACT may include an oxide semiconductor. In an embodiment, each of the active layers ACT may be made of a Zn oxide-based material such as Zn oxide, In—Zn oxide or Ga—In—Zn oxide or may be an In—Ga—Zn—O (IGZO) semiconductor containing metals such as indium (In) and gallium (Ga) in ZnO. However, the disclosure is not limited thereto. For example, the active layers ACT may also include amorphous silicon or polysilicon.

The gate electrodes GE of the light emitting unit 100 may be disposed on the active layers ACT. The gate electrodes GE may overlap the active layers ACT in the display area DA. In an embodiment, the gate electrodes GE may be narrower than the active layers ACT, but the disclosure is not limited thereto.

In an embodiment, in consideration of adhesion to an adjacent layer, surface flatness of a layer on which it is stacked, and workability, each of the gate electrodes GE may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu) and may be formed as a single layer or a multilayer, but the disclosure is not limited thereto.

The gate insulating layers GI of the light emitting unit 100 may be disposed between the active layers ACT and the gate electrodes GE. The gate insulating layers GI may insulate the active layers ACT from the gate electrodes GE. In an embodiment, the gate insulating layers GI may have a partially patterned shape instead of being formed as one layer or a layer disposed on a surface of the first substrate 110 on the first side in the third direction DR3. The gate insulating layers GI may be narrower than the active layers ACT and may be wider than the gate electrodes GE, but the disclosure is not limited thereto.

In an embodiment, the gate insulating layers GI may include an inorganic material. For example, the gate insulating layers GI may include one of the inorganic materials included in the description of the first insulating layer 130.

The second insulating layer 150 of the light emitting unit 100 may be disposed on the gate insulating layers GI to cover the active layers ACT and the gate electrodes GE. In an embodiment, the second insulating layer 150 may function as a planarization layer that provides a flat surface.

The second insulating layer 150 may include an organic material. In an embodiment, the second insulating layer 150 may include, but is not limited to, at least any one of photo acryl (PAC), polystyrene, polymethyl methacrylate (PMMA), polyacrylonitrile (PAN), polyamide, polyimide, polyarylether, heterocyclic polymer, parylene, fluorine-based polymer, epoxy resin, benzocyclobutene series resin, siloxane series resin, and silane resin.

The source electrodes SE and the drain electrodes DE of the light emitting unit 100 may be spaced apart from each other on the second insulating layer 150. The source electrodes SE and the drain electrodes DE may be connected to the active layers ACT respectively through contact holes penetrating the second insulating layer 150. In an embodiment, the source electrodes SE may penetrate the first insulating layer 130 as well as the second insulating layer 150 and thus may be connected to the bottom metal layers BML. In case that the bottom metal layers BML are part of lines that transmit signals or voltages, the source electrodes SE may be connected and electrically coupled or connected to the bottom metal layers BML to receive voltages provided to the lines. By way of example, in case that the bottom metal layers BML are floating patterns rather than lines, voltages applied to the source electrodes SE may be transmitted to the bottom metal layers BML.

Each of the source electrodes SE and the drain electrodes DE may include aluminum (Al), copper (Cu), titanium (Ti), or the like and may be formed as a multilayer or a single layer. In an embodiment, the source electrodes SE and the drain electrodes DE may have, but are not limited to, a multilayer structure of Ti/Al/Ti.

The active layers ACT, the gate electrodes GE, the source electrodes SE, and the drain electrodes DE described above may form thin-film transistors which are switching elements. In an embodiment, the thin-film transistors may be located in the first light emitting area EA1, the second light emitting area EA2, and the third light emitting area EA3, respectively. In an embodiment, a portion of each of the thin-film transistors may be located in the non-light emitting area NELA.

The third insulating layer 160 of the light emitting unit 100 may be disposed on the second insulating layer 150 to cover the thin-film transistors. In an embodiment, the third insulating layer 160 may be a planarization layer.

The third insulating layer 160 may be made of an organic material. In an embodiment, the third insulating layer 160 may include acrylic resin, epoxy resin, imide resin or ester resin or may include a photosensitive organic material, but the disclosure is not limited thereto.

Pixel electrodes PE may be located on the third insulating layer 160 in the display area DA of the light emitting unit 100.

The pixel electrodes PE may overlap the first light emitting area EA1, the second light emitting area EA2 and the third light emitting area EA3, respectively, and at least a portion of each of the pixel electrodes PE may extend to the non-light emitting area NELA. The pixel electrodes PE may be connected to the drain electrodes DE of the thin-film transistors.

In an embodiment, the pixel electrodes PE may be reflective electrodes. In this case, each of the pixel electrodes PE may be a metal layer including a metal such as Ag, Mg, Al, Pt, Pd, Au, Ni, Nd, Ir or Cr. In an embodiment, each of the pixel electrodes PE may further include a metal oxide layer stacked on the metal layer. In an embodiment, the pixel electrodes PE may have a multilayer structure, for example, a two-layer structure of ITO/Ag, Ag/ITO, ITO/Mg or ITO/MgF or a three-layer structure of ITO/Ag/ITO.

The pixel defining layer PDL of the light emitting unit 100 may be disposed on the pixel electrodes PE. The pixel defining layer PDL may define the first light emitting area EA1, the second light emitting area EA2, and the third light emitting area EA3 as openings that expose the pixel electrodes PE.

The pixel defining layer PDL may overlap the light blocking area BA of the color filter member 320, which will be described later, in the third direction DR3. The pixel defining layer PDL may overlap a bank member BK, which will be described later, in the third direction DR3.

In an embodiment, the pixel defining layer PDL may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB). However, the disclosure is not limited thereto.

A light emitting layer OL of the light emitting unit 100 may be disposed on the pixel electrodes PE. In an embodiment, the light emitting layer OL may be in the shape of a continuous layer formed over the light emitting areas EA1 through EA3 and the non-light emitting area NELA. In an embodiment, the light emitting layer OL may be located only in the display area DA. However, the disclosure is not limited thereto. For example, a portion of the light emitting layer OL may be further disposed in the non-display area NDA. The light emitting layer OL will be described in more detail later.

A cathode CE of the light emitting unit 100 may be disposed on the light emitting layer OL. In an embodiment, the cathode CE may be disposed on the light emitting layer OL and may be in the shape of a continuous layer formed over the light emitting areas EA1 through EA3 and the non-light emitting area NELA. In other words, the cathode CE may completely cover the light emitting layer OL.

The cathode CE may have translucency or transparency. In case that a thickness of the cathode CE is tens to hundreds of angstroms, the cathode CE may have translucency. In an embodiment, in case that the cathode CE has translucency, it may include Ag, Mg, Cu, Al, Pt, Pd, Au, Ni, Nd, Ir, Cr, Li, Ca, LiF/Ca, LiF/Al, Mo, Ti, or a compound or mixture thereof (for example, a mixture of Ag and Mg). The cathode CE may also have transparency by including a transparent conductive oxide. In an embodiment, in case that the cathode CE has transparency, it may include tungsten oxide (WₓOₓ), titanium oxide (TiO₂), indium tin oxide (ITO), indium zinc oxide (IZO)), zinc oxide (ZnO) indium tin zinc oxide (ITZO), or magnesium oxide (MgO).

The pixel electrodes PE, the light emitting layer OL, and the cathode CE may form light emitting elements. For example, the pixel electrode PE, the light emitting layer OL and the cathode CE overlapping the first light emitting area EA1 may form a first light emitting element, the pixel electrode PE, the light emitting layer OL and the cathode CE overlapping the second light emitting area EA2 may form a second light emitting element, and the pixel electrode PE, the light emitting layer OL and the cathode CE overlapping the third light emitting area EA3 may form a third light emitting element. Each of the first light emitting element, the second light emitting element, and the third light emitting element may emit output light LE.

The output light LE finally emitted from the light emitting layer OL may be a mixture of a first component LE1 and a second component LE2. Each of the first component LE1 and the second component LE2 in the output light LE may have a peak wavelength in the range of about 440 to less than about 480 nm. For example, the output light LE may be blue light.

In an embodiment, the light emitting layer OL may have a structure in which light emitting material layers overlap as illustrated in FIG. 5, for example, may have a tandem structure. For example, the light emitting layer OL may include a first stack ST1 including a first light emitting material layer EML1, a second stack ST2 located on the first stack ST1 and including a second light emitting material layer EML2, a third stack ST3 located on the second stack ST2 and including a third light emitting material layer EML3, a first charge generation layer CGL1 located between the first stack ST1 and the second stack ST2, and a second charge generation layer CGL2 located between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other.

In an embodiment, the first light emitting material layer EML1, the second light emitting material layer EML2, and the third light emitting material layer EML3 may all emit light of the first color, for example, blue light. For example, each of the first light emitting material layer EML1, the second light emitting material layer EML2, and the third light emitting material layer EML3 may be a blue light emitting layer and may include an organic material.

In an embodiment, at least any one of the first light emitting material layer EML1, the second light emitting material layer EML2 and the third light emitting material layer EML3 may emit first blue light having a first peak wavelength, and at least another one of the first light emitting material layer EML1, the second light emitting material layer EML2 and the third light emitting material layer EML3 may emit second blue light having a second peak wavelength different from the first peak wavelength. For example, any one of the first light emitting material layer EML1, the second light emitting material layer EML2 and the third light emitting material layer EML3 may emit the first blue light having the first peak wavelength, and the other two of the first light emitting material layer EML1, the second light emitting material layer EML2 and the third light emitting material layer EML3 may emit the second blue light having the second peak wavelength. For example, the output light LE finally emitted from the light emitting layer OL may be a mixture of the first component LE1 and the second component LE2. Here, the first component LE1 may be the first blue light having the first peak wavelength, and the second component LE2 may be the second blue light having the second peak wavelength.

In an embodiment, any one of the first peak wavelength and the second peak wavelength may be in the range of about 440 to less than about 460 nm. The other one of the first peak wavelength and the second peak wavelength may be in the range of about 460 to about 480 nm. However, the range of the first peak wavelength and the range of the second peak wavelength are not limited to this example. For example, both the range of the first peak wavelength and the range of the second peak wavelength may include about 460 nm. In an embodiment, any one of the first blue light and the second blue light may be light of a deep blue color, and the other one of the first blue light and the second blue light may be light of a sky blue color.

According to an embodiment, the output light LE emitted from the light emitting layer OL may be blue light and may include a long wavelength component and a short wavelength component. Therefore, the light emitting layer OL may finally emit blue light having a broader emission peak as the output light LE, thereby improving color visibility at a side viewing angle compared with a conventional light emitting element that emits blue light having a sharp emission peak.

In an embodiment, each of the first light emitting material layer EML1, the second light emitting material layer EML2, and the third light emitting material layer EML3 may include a host and a dopant. The host is not particularly limited as long as it is a commonly used material. However, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl) anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl) anthracene (TBADN), distyrylarylene (DSA), 4,4′-bis(9-carbazolyl)-2,2′-dimethyl-biphenyl (CDBP), or 2-methyl-9,10-bis(naphthalen-2-yl) anthracene) (MADN) may be used.

Each of the first light emitting material layer EML1, the second light emitting material layer EML2, and the third light emitting material layer EML3 which emit blue light may include, for example, a fluorescent material including any one of spiro-DPVBi, spiro-6P, distyryl-benzene (DSB), distyryl-arylene (DSA), a polyfluorene (PFO)-based polymer, and a poly(p-phenylene vinylene) (PPV)-based polymer. By way of example, a phosphorescent material including an organometallic complex such as (4,6-F2ppy) 2Irpic may be included.

As described above, at least one of the first light emitting material layer EML1, the second light emitting material layer EML2 and the third light emitting material layer EML3 and at least another one of the first light emitting material layer EML1, the second light emitting material layer EML2 and the third light emitting material layer EML3 emit blue light in different wavelength ranges. To emit blue light in different wavelength ranges, the first light emitting material layer EML1, the second light emitting material layer EML2 and the third light emitting material layer EML3 may include a same material, and a resonance distance may be adjusted. By way of example, to emit blue light in different wavelength ranges, at least one of the first light emitting material layer EML1, the second light emitting material layer EML2 and the third light emitting material layer EML3 and at least another one of the first light emitting material layer EML1, the second light emitting material layer EML2 and the third light emitting material layer EML3 may include different materials.

However, the disclosure is not limited thereto. The first light emitting material layer EML1, the second light emitting material layer EML2 and the third light emitting material layer EML3 may all emit blue light having a peak wavelength in a range of about 440 to about 480 nm and may be made of a same material.

By way of example, in an embodiment, at least any one of the first light emitting material layer EML1, the second light emitting material layer EML2 and the third light emitting material layer EML3 may emit the first blue light having the first peak wavelength, another one of the first light emitting material layer EML1, the second light emitting material layer EML2 and the third light emitting material layer EML3 may emit the second blue light having the second peak wavelength different from the first peak wavelength, and the other one of the first light emitting material layer EML1, the second light emitting material layer EML2 and the third light emitting material layer EML3 may emit third blue light having a third peak wavelength different from the first peak wavelength and the second peak wavelength. In an embodiment, any one of the first peak wavelength, the second peak wavelength and the third peak wavelength may be in the range of about 440 to less than about 460 nm. Another one of the first peak wavelength, the second peak wavelength and the third peak wavelength may be in the range of about 460 to less than about 470 nm, and the other one of the first peak wavelength, the second peak wavelength and the third peak wavelength may be in the range of about 470 to about 480 nm.

According to an embodiment, the output light LE emitted from the light emitting layer OL is blue light and may include a long wavelength component, a medium wavelength component and a short wavelength component. Therefore, the light emitting layer OL may finally emit blue light having a broader emission peak as the output light LE and improve color visibility at a side viewing angle.

According to the above-described embodiments, it is possible to improve light efficiency and extend the life of the display device 1 as compared with a conventional light emitting element that does not employ a tandem structure, for example, a structure in which light emitting layers OL are stacked each other.

By way of example, in an embodiment, at least any one of the first light emitting material layer EML1, the second light emitting material layer EML2 and the third light emitting material layer EML3 may emit light of the first color, for example, blue light, and at least another one of the first light emitting material layer EML1, the second light emitting material layer EML2 and the third light emitting material layer EML3 may emit light of the second color, for example, green light. In an embodiment, blue light emitted from at least any one of the first light emitting material layer EML1, the second light emitting material layer EML2, and the third light emitting material layer EML3 may have a peak wavelength in the range of about 440 to about 480 nm or about 460 to about 480 nm. Green light emitted from at least another one of the first light emitting material layer EML1, the second light emitting material layer EML2, and the third light emitting material layer EML3 may have a peak wavelength in the range of about 510 to about 550 nm.

For example, any one of the first light emitting material layer EML1, the second light emitting material layer EML2 and the third light emitting material layer EML3 may be a green light emitting layer OL emitting green light, and the other two of the first light emitting material layer EML1, the second light emitting material layer EML2 and the third light emitting material layer EML3 may be blue light emitting material layers OL emitting blue light. In case that the other two of the first light emitting material layer EML1, the second light emitting material layer EML2 and the third light emitting material layer EML3 are blue light emitting material layers OL, peak wavelengths of blue light emitted from the two blue light emitting layers OL may be in the same range or in different ranges.

According to an embodiment, the output light LE emitted from the light emitting layer OL may be a mixture of the first component LE1 which is blue light and the second component LE2 which is green light. For example, in case that the first component LE1 is dark blue light and the second component LE2 is green light, the output light LE may be light having a sky blue color. As in the above-described embodiments, the output light LE emitted from the light emitting layer OL, which is a mixture of blue light and green light, may include a long wavelength component and a short wavelength component. Therefore, the light emitting layer OL may finally emit blue light having a broader emission peak as the output light LE and improve color visibility at a side viewing angle. Since the second component LE2 of the output light LE is green light, a green light component can be supplemented in the light provided from the display device 1 to the outside. Accordingly, the color reproducibility of the display device 1 can be improved.

In an embodiment, a green light emitting material layer among the first light emitting material layer EML1, the second light emitting material layer EML2, and the third light emitting material layer EML3 may include a host and a dopant. The host included in the green light emitting material layer is not particularly limited as long as it is a commonly used material. However, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl) anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl) anthracene (TBADN), distyrylarylene (DSA), 4,4′-bis(9-carbazolyl)-2,2′-dimethyl-biphenyl (CDBP), or 2-methyl-9,10-bis(naphthalen-2-yl) anthracene) (MADN) may be used.

The dopant included in the green light emitting material layer may be, for example, a fluorescent material including tris-(8-hydroyquinolato)aluminum(III) (Alq3) or may be a phosphorescent material such as Ir(ppy)3(fac tris(2-phenylpyridine)iridium), Ir(ppy)2(acac)(Bis(2-phenylpyridine)(acetylacetonate)iridium(III)) or Ir(mpyp)3(2-phenyl-4-methyl-pyridine iridium).

The first charge generation layer CGL1 may be located between the first stack ST1 and the second stack ST2. The first charge generation layer CGL1 may inject electric charges into each light emitting layer OL. The first charge generation layer CGL1 may control the charge balance between the first stack ST1 and the second stack ST2. The first charge generation layer CGL1 may include an n-type charge generation layer CGL11 and a p-type charge generation layer CGL12. The p-type charge generation layer CGL12 may be disposed on the n-type charge generation layer CGL11 and may be located between the n-type charge generation layer CGL11 and the second stack ST2.

The first charge generation layer CGL1 may have a structure in which the n-type charge generation layer CGL11 and the p-type charge generation layer CGL12 are in contact with each other. The n-type charge generation layer CGL11 is disposed closer to a pixel electrode PE1 among the pixel electrode PE1 and the cathode CE. The p-type charge generation layer CGL12 is disposed closer to the cathode CE among the pixel electrode PE1 and the cathode CE. The n-type charge generation layer CGL11 supplies electrons to the first light emitting material layer EML1 adjacent to the pixel electrode PE1, and the p-type charge generation layer CGL12 supplies holes to the second light emitting material layer EML2 included in the second stack ST2. Since the first charge generation layer CGL1 is disposed between the first stack ST1 and the second stack ST2 to provide electric charges to each light emitting layer OL, luminous efficiency can be improved, and a driving voltage can be lowered.

In FIG. 4, the pixel electrode PE corresponding to the first light emitting area EA1 may be defined as a first pixel electrode PE1 (for example, the first pixel electrode PE1 of a first pixel PX1), the pixel electrode PE corresponding to the second light emitting area EA2 may be defined as a second pixel electrode PE2 (for example, the second pixel electrode PE2 of a second pixel PX2), and the pixel electrode PE corresponding to the third light emitting area EA3 may be defined as a third pixel electrode PE3 (for example, the third pixel electrode PE3 of a third pixel PX3). In this case, the first stack ST1 may be located on the first pixel electrode PE1, the second pixel electrode PE2 and the third pixel electrode PE3 and may further include a first hole transport layer HTL1, a first electron blocking layer BIL1 and a first electron transport layer ETL1.

The first hole transport layer HTL1 may be located on the first pixel electrode PE1, the second pixel electrode PE2, and the third pixel electrode PE3. The first hole transport layer HTL1 may facilitate the transportation of holes and may include a hole transport material. The hole transport material may include, but is not limited to, a carbazole derivative such as N-phenylcarbazole or polyvinylcarbazole; a fluorene derivative; a triphenylamine derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA); N,N′-di(1-naphthyl)-N,N′-diphenylbenzidine) (NPB); or 4,4′-Cyclohexylidene bis[N,N-bis(4-methylphenyl)benzenamine] (TAPC).

The first electron blocking layer BIL1 may be located on the first hole transport layer HTL1 and may be located between the first hole transport layer HTL1 and the first light emitting material layer EML1. The first electron blocking layer BIL1 may include a hole transport material and a metal or a metal compound in order to prevent electrons generated by the first light emitting material layer EML1 from entering the first hole transport layer HTL1. In an embodiment, the first hole transport layer HTL1 and the first electron blocking layer BIL1 described above may be formed as a single layer in which their respective materials are mixed.

The first electron transport layer ETL1 may be located on the first light emitting material layer EML1 and may be located between the first charge generation layer CGL1 and the first light emitting material layer EML1. In an embodiment, the first electron transport layer ETL1 may include an electron transport material such as tris-(8-hydroxyquinolinato)aluminum (Alq3), 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphalene-2-yl) anthracene (ADN), or a mixture thereof. However, the disclosure is not limited to the type of the electron transport material. The second stack ST2 may be located on the first charge generation layer CGL1 and may further include a second hole transport layer HTL2, a second electron blocking layer BIL2 and a second electron transport layer ETL2.

The second hole transport layer HTL2 may be located on the first charge generation layer CGL1. The second hole transport layer HTL2 may be made of a same material as the first hole transport layer HTL1 or may include one or more materials selected from the materials described as the materials included in the first hole transport layer HTL1. The second hole transport layer HTL2 may be composed of a single layer or layers.

The second electron blocking layer BIL2 may be located on the second hole transport layer HTL2 and may be located between the second hole transport layer HTL2 and the second light emitting material layer EML2. The second electron blocking layer BIL2 may have a same material and structure as the first electron blocking layer BIL1 or may include one or more materials selected from the materials described as the materials included in the first electron blocking layer BIL1.

The second electron transport layer ETL2 may be located on the second light emitting material layer EML2 and may be located between the second charge generation layer CGL2 and the second light emitting material layer EML2. The second electron transport layer ETL2 may have a same material and structure as the first electron transport layer ETL1 or may include one or more materials selected from the materials described as the materials included in the first electron transport layer ETL1. The second electron transport layer ETL2 may be composed of a single layer or layers.

The second charge generation layer CGL2 may be located on the second stack ST2 and may be located between the second stack ST2 and the third stack ST3.

The second charge generation layer CGL2 may have the same structure as the first charge generation layer CGL1 described above. For example, the second charge generation layer CGL2 may include an n-type charge generation layer CGL21 disposed closer to the second stack ST2 and a p-type charge generation layer CGL22 disposed closer to the cathode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 are in contact with each other. The first charge generation layer CGL1 and the second charge generation layer CGL2 may be made of different materials or a same material.

The third stack ST3 may be located on the second charge generation layer CGL2 and may further include a third hole transport layer HTL3 and a third electron transport layer ETL3.

The third hole transport layer HTL3 may be located on the second charge generation layer CGL2. The third hole transport layer HTL3 may be made of a same material as the first hole transport layer HTL1 or may include one or more materials selected from the materials described as the materials included in the first hole transport layer HTL1. The third hole transport layer HTL3 may be composed of a single layer or layers. In case that the third hole transport layer HTL3 is composed of layers, the layers may include different materials.

The third electron transport layer ETL3 may be located on the third light emitting material layer EML3 and may be located between the cathode CE and the third light emitting material layer EML3. The third electron transport layer ETL3 may have a same material and structure as the first electron transport layer ETL1 or may include one or more materials selected from the materials described as the materials included in the first electron transport layer ETL1. The third electron transport layer ETL3 may be composed of a single layer or layers. In case that the third electron transport layer ETL3 is composed of layers, the layers may include different materials.

Although not illustrated in the drawing, a hole injection layer may be further located in at least any one of the spaces between the first stack ST1 and the first pixel electrode PE1, the second pixel electrode PE2 and the third pixel electrode PE3, between the second stack ST2 and the first charge generation layer CGL1, and between the third stack ST3 and the second charge generation layer CGL2. The hole injection layer may facilitate the injection of holes into the first light emitting material layer EML1, the second light emitting material layer EML2 and the third light emitting material layer EML3. In an embodiment, the hole injection layer may be made of, but not limited to, any one or more of cuper phthalocyanine (CuPc), poly(3,4-ethylenedioxythiphene) (PEDOT), polyaniline (PANI), and N,N-dinaphthyl-N,N′-diphenyl benzidine (NPD). In an embodiment, the hole injection layer may be located between the first stack ST1 and the first pixel electrode PE1, the second pixel electrode PE2 and the third pixel electrode PE3, between the second stack ST2 and the first charge generation layer CGL1, and between the third stack ST3 and the second charge generation layer CGL2.

Although not illustrated in the drawing, an electron injection layer may be further located in at least any one of the spaces between the third electron transport layer ETL3 and the cathode CE, between the second charge generation layer CGL2 and the second stack ST2, and between the first charge generation layer CGL1 and the first stack ST1. The electron injection layer may facilitate the injection of electrons and may use tris(8-hydroxyquinolino)aluminum) (Alq3), PBD, TAZ, spiro-PBD, BAlq or SAlq, but the disclosure is not limited thereto. The electron injection layer may be a metal halide compound, for example, any one or more of MgF₂, LiF, NaF, KF, RbF, CsF, FrF, LiI, NaI, KI, RbI, CsI, FrI and CaF₂, but the disclosure is not limited thereto. By way of example, the electron injection layer may include a lanthanum material such as Yb, Sm, or Eu. By way of example, the electron injection layer may include both a metal halide material and a lanthanum material such as RbI:Yb or KI:Yb. In case that the electron injection layer may include both a metal halide material and a lanthanum material, the electron injection layer may be formed by co-deposition of the metal halide material and the lanthanum material. In an embodiment, the electron injection layer may be located between the third electron transport layer ETL3 and the cathode CE, between the second charge generation layer CGL2 and the second stack ST2, and between the first charge generation layer CGL1 and the first stack ST1.

In an embodiment, the light emitting layer OL may not include a red light emitting material layer and thus may not emit light of the third color, for example, red light. In other words, the output light LE may not include a light component having a peak wavelength in the range of about 610 to about 650 nm and may include only a light component having a peak wavelength in the range of about 440 to about 550 nm.

Referring back to FIG. 4, the first capping layer CPL1 may be disposed on the cathode CE. The first capping layer CPL1 may improve viewing angle characteristics and increase external light emission efficiency. The first capping layer CPL1 may be commonly disposed in the first light emitting area EA1, the second light emitting area EA2, the third light emitting area EA3, and the non-light emitting area NELA. The first capping layer CPL1 may completely cover the cathode CE.

The first capping layer CPL1 may include at least any one of an inorganic material and an organic material having light transmitting properties. In other words, the first capping layer CPL1 may be made of an inorganic layer or an organic layer or may be made of an organic layer TFEb including inorganic particles. In an embodiment, the first capping layer CPL1 may include, but is not limited to, a triamine derivative, a carbazole biphenyl derivative, an arylenediamine derivative, or an aluminum quinolium complex (Alq3).

The thin-film encapsulation layer TFE of the light emitting unit 100 may be disposed on the first capping layer CPL1. The thin-film encapsulation layer TFE may protect elements located under or below the thin-film encapsulation layer TFE from external foreign substances such as moisture. The thin-film encapsulation layer TFE is commonly disposed in the first light emitting area EA1, the second light emitting area EA2, the third light emitting area EA3, and the non-light emitting area NELA. The thin-film encapsulation layer TFE may completely cover the first capping layer CPL1.

The thin-film encapsulation layer TFE may include a lower inorganic layer TFEa, an organic layer TFEb, and an upper inorganic layer TFEc sequentially stacked each other on the first capping layer CPL1.

The lower inorganic layer TFEa may completely cover the first capping layer CPL1 in the display area DA to cover the first light emitting element, the second light emitting element and the third light emitting element.

The organic layer TFEb may be disposed on the lower inorganic layer TFEa to cover the first light emitting element, the second light emitting element and the third light emitting element.

The upper inorganic layer TFEc may be disposed on the organic layer TFEb to completely cover the organic layer TFEb.

In an embodiment, each of the lower inorganic layer TFEa and the upper inorganic layer TFEc may be made of, but not limited to, silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or lithium fluoride.

In an embodiment, the organic layer TFEb may be made of, but not limited to, acrylic resin, methacrylic resin, polyisoprene, vinyl resin, epoxy resin, urethane resin, cellulose resin, or perylene resin.

The light transmitting unit 300 may have a structure in which a second substrate 310, the color filter member 320, a second capping layer CPL2, the bank member BK, light transmitting members, and a third capping layer CPL3 are sequentially stacked each other to the second side in the third direction DR3.

The light transmitting unit 300 may have a structure in which the second substrate 310, the color filter member 320, the second capping layer CPL2, the light transmitting members, the bank member BK, and the third capping layer CPL3 are sequentially stacked each other to the second side in the third direction DR3.

The second substrate 310 of the light transmitting unit 300 may serve as a base of the light transmitting unit 300. The second substrate 310 may be made of a light transmitting material. The second substrate 310 may be a glass substrate or a plastic substrate. In case that the second substrate 310 is a plastic substrate, it may have flexibility. In an embodiment, in case that the second substrate 310 is a plastic substrate, it may include, but is not limited to, polyimide. Since the light emitting unit 100 and the light transmitting unit 300 face each other in the third direction DR3 as described above, the first substrate 110 of the light emitting unit 100 and the second substrate 310 of the light transmitting unit 300 may face each other in the third direction DR3.

The color filter member 320 of the light transmitting unit 300 may be disposed on a second side of the second substrate 310 in the third direction DR3, for example, between the second substrate 310 and the light emitting unit 100. The color filter member 320 may include filtering pattern areas and a light blocking pattern portion BM. The light blocking pattern portion BM may surround the filtering pattern areas. The filtering pattern areas of the color filter member 320 may define light transmitting areas of the light transmitting unit 300, and the light blocking pattern portion BM may define the light blocking area BA of the light transmitting unit 300.

The color filter member 320 may include a first color filter CF1, a second color filter CF2, and a third color filter CF3. The first color filter CF1 may absorb both the second light and the third light except for the first light, the second color filter CF2 may absorb both the first light and the third light except for the second light, and the third color filter CF3 may absorb both the first light and the second light except for the third light. In other words, the first color filter CF1 may transmit the first light, the second color filter CF2 may transmit the second light, and the third color filter CF3 may transmit the third light.

In an embodiment, the first color filter CF1 may be a blue color filter and may include a blue colorant. As used herein, the term “colorant” is a concept encompassing both a dye and a pigment. The first color filter CF1 may include a base resin, and the blue colorant may be dispersed in the base resin. In an embodiment, the second color filter CF2 may be a green color filter and may include a green colorant. The second color filter CF2 may include a base resin, and the green colorant may be dispersed in the base resin. In an embodiment, the third color filter CF3 may be a red color filter and may include a red colorant. The third color filter CF3 may include a base resin, and the red colorant may be dispersed in the base resin.

The first color filter CF1 may include a first filtering pattern area 321a and a first light blocking pattern area 321b surrounding the first filtering pattern area 321a. The second color filter CF2 may include a second filtering pattern area 322a and a second light blocking pattern area 322b surrounding the second filtering pattern area 322a. The third color filter CF3 may include a third filtering pattern area 323a and a third light blocking pattern area 323b surrounding the third filtering pattern area 323a. For example, the first filtering pattern area 321a of the first color filter CF1 may overlap the first light transmitting area TA1, and the first light blocking pattern area 321b of the first color filter CF1 may surround the first filtering pattern area 321a overlapping the first light transmitting area TA1. However, the first light blocking pattern area 321b of the first color filter CF1 may not overlap the second light transmitting area TA2 and the third light transmitting area TA3 and may overlap the light blocking area BA. The second filtering pattern area 322a of the second color filter CF2 may overlap the second light transmitting area TA2, and the second light blocking pattern area 322b of the second color filter CF2 may surround the second filtering pattern area 322a overlapping the second light transmitting area TA2. However, the second light blocking pattern area 322b of the second color filter CF2 may not overlap the first light transmitting area TA1 and the third light transmitting area TA3 and may overlap the light blocking area BA. The third filtering pattern area 323a of the third color filter CF3 may overlap the third light transmitting area TA3, and the third light blocking pattern area 323b of the third color filter CF3 may surround the third filtering pattern area 323a overlapping the third light transmitting area TA3. However, the third light blocking pattern area 323b of the third color filter CF3 may not overlap the first light transmitting area TA1 and the second light transmitting area TA2 and may overlap the light blocking area BA. In other words, the filtering pattern areas of the color filter member 320 may include the first filtering pattern area 321a of the first color filter CF1, the second filtering pattern area 322a of the second color filter CF2 and the third filtering pattern area 323a of the third color filter CF3, and the light blocking pattern portion BM may have a structure in which the first light blocking pattern area 321b of the first color filter CF1, the second light blocking pattern area 322b of the second color filter CF2, and the third light blocking pattern area 323b of the third color filter CF3 are stacked each other.

The first filtering pattern area 321a of the first color filter CF1 may function as a blocking filter that blocks red light and green light. For example, the first filtering pattern area 321a may selectively transmit the first light (for example, blue light) and block or absorb the second light (for example, green light) and the third color light (for example, red light).

The second filtering pattern area 322a of the second color filter CF2 may function as a blocking filter that blocks blue light and red light. For example, the second filtering pattern area 322a may selectively transmit the second light (for example, green light) and block or absorb the first light (for example, blue light) and the third light (for example, red light).

The third filtering pattern area 323a of the third color filter CF3 may function as a blocking filter that blocks blue light and green light. For example, the third filtering pattern area 323a may selectively transmit the third light (for example, red light) and block or absorb the first light (for example, blue light) and the second light (for example, green light).

In an embodiment, the light blocking pattern portion BM may have a structure in which the first light blocking pattern area 321b, the third light blocking pattern area 323b, and the second light blocking pattern area 322b are sequentially stacked each other in the third direction DR3. However, the disclosure is not limited thereto. For example, the light blocking pattern portion BM may not be composed of the color filters 321 through 323 described above, but may be formed of an organic light blocking material, for example, may be formed by coating and exposing an organic light blocking material. For ease of description, a case where the light blocking pattern portion BM has a structure in which the first light blocking pattern area 321b, the third light blocking pattern area 323b, and the second light blocking pattern area 322b are sequentially stacked each other in the third direction DR3 will be described below. The light blocking pattern portion BM may absorb all of the first light, the second light, and the third light through the above-described configuration.

A low refractive layer LR may be disposed on the color filter member 320. The low refractive layer LR may have a lower refractive index than a first light transmitting member TPL, a second light transmitting member WCL1, and a third light transmitting member WCL2 which will be described later. Therefore, the low refractive layer LR may induce total reflection of light travelling from the first light transmitting member TPL, the second light transmitting member WCL2 and the third light transmitting member WCL2 to the low refractive layer LR, thereby reusing the light.

In an embodiment, the refractive index of the low refractive layer LR may be 1.3 or less. In case that the refractive index of the low refractive layer LR is 1.3 or less, total reflection of light may fully occur because the refractive index of the low refractive layer LR is greatly different from those of the first light transmitting member TPL, the second light transmitting member WCL1, and the third light transmitting member WCL2.

The low refractive layer LR may compensate for and planarize step differences caused by the light blocking pattern areas 321b, 322b and 323b of the color filter member 320. Accordingly, the second capping layer CPL2 on the low refractive layer LR may be formed to be flat.

The second capping layer CPL2 of the light transmitting unit 300 may be disposed on a surface of the low refractive layer LR to cover the low refractive layer LR. The second capping layer CPL2 may prevent damage to or contamination of the low refractive layer LR and the light blocking pattern portion BM and the filtering pattern areas of the color filter member 320 by preventing penetration of impurities such as moisture or air from the outside into the low refractive layer LR or the color filter member 320.

The second capping layer CPL2 may include an inorganic material. The second capping layer CPL2 may directly contact the low refractive layer LR.

The bank member BK of the light transmitting unit 300 may be disposed on a surface of the second capping layer CPL2 on the second side in the third direction DR3 based on FIG. 4, and portions of the bank member BK may be spaced apart from each other in the second direction DR2 to form spaces for accommodating the light transmitting members which will be described later. For example, the bank member BK may define the spaces in which the light transmitting members to be described later are disposed. The bank member BK may directly contact the surface of the second capping layer CPL2 on the second side in the third direction DR3. The bank member BK may surround the light transmitting members, which will be described later, in plan view. The bank member BK may overlap the non-light emitting area NELA of the light emitting unit 100 and the light blocking area BA of the light transmitting unit 300. The bank member BK may not overlap the light emitting areas EA1, EA2 and EA3 of the light emitting unit 100 and the light transmitting areas TA1, TA2 and TA3 of the light transmitting unit 300.

In an embodiment, the bank member BK may include, but is not limited to, a photocurable organic material or a photocurable organic material including a light blocking material.

The light transmitting members of the light transmitting unit 300 may be disposed on the surface of the second capping layer CPL2 on the second side in the third direction DR3 which is exposed by the spaces between the portions of the bank member BK. The light transmitting members may include the first light transmitting member TPL overlapping the first light transmitting area TA1, the second light transmitting member WCL1 overlapping the second light transmitting area TA2, and the third light transmitting member WCL2 overlapping the third light transmitting area TA3. The first light transmitting member TPL, the second light transmitting member WCL1, and the third light transmitting member WCL2 may be referred to as wavelength conversion layers or wavelength conversion material layers in the claims.

The first light transmitting member TPL may be disposed in a space defined by the bank member BK and may overlap the first light emitting area EA1 and the first light transmitting area TA1 in the third direction DR3. The first light transmitting member TPL may directly contact the second capping layer CPL2 and the bank member BK.

The first light transmitting member TPL may be a light transmitting pattern that transmits incident light. For example, the output light LE provided by the first light emitting element may be blue light as described above and may pass through the first light transmitting member TPL and the first filtering pattern area 321a of the first color filter CF1 to exit the display device 1. In other words, first output light L1 emitted from the first light emitting area EA1 to the outside through the first light transmitting area TA1 may be blue light.

The first light transmitting member TPL may include a base resin 330 and light scatterers 331.

The base resin 330 may be made of an organic material having high light transmittance. In an embodiment, the base resin 330 may include, but is not limited to, an organic material such as epoxy resin, acrylic resin, cardo resin, or imide resin.

The light scatterers 331 may have a refractive index different from that of the base resin 330 and may form an optical interface with the base resin 330. The light scatterers 331 may be light scattering particles. The light scatterers 331 may scatter incident light in random directions regardless of the incident direction of the incident light without substantially converting the wavelength of the incident light passing through the light transmitting area TA1.

The light scatterers 331 may be materials that scatter at least a portion of transmitted light and may include metal oxide particles or organic particles. In an embodiment, the light scatterers 331 may include titanium oxide (TiO₂), zirconium oxide (ZrO₂), aluminum oxide (Al₂O₃), indium oxide (In₂O₃), zinc oxide (ZnO) or tin oxide (SnO₂) as the metal oxide and may include acrylic resin or urethane resin as the organic particles, but the disclosure is not limited thereto.

The second light transmitting member WCL1 may be disposed in a space defined by the bank member BK and may overlap the second light emitting area EA2 and the second light transmitting area TA2 in the third direction DR3. The second light transmitting member WCL1 may directly contact the second capping layer CPL2 and the bank member BK.

The second light transmitting member WCL1 may be a wavelength converting pattern that converts or shifts a peak wavelength of incident light into another given peak wavelength and outputs light having the given peak wavelength. For example, the output light LE provided by the second light emitting element may be blue light as described above and may be converted into green light having a peak wavelength in the range of about 510 to about 550 nm as it passes through the second light transmitting member WCL1 and the second filtering pattern area 322a of the second color filter CF2. Accordingly, the green light may be emitted to the outside of the display device 1. In other words, second output light L2 emitted from the second light emitting area EA2 to the outside through the second light transmitting area TA2 may be green light.

The second light transmitting member WCL1 may include a base resin 330, light scatterers 331 dispersed in the base resin 330, and first wavelength shifters 332 dispersed in the base resin 330.

The first wavelength shifters 332 may convert or shift a peak wavelength of incident light to another given peak wavelength. The first wavelength shifters 332 may convert the output light LE, which is blue light provided by the second light emitting element, into green light having a single peak wavelength in the range of about 510 to about 550 nm and output the green light.

In an embodiment, the first wavelength shifters 332 may be, but are not limited to, quantum dots, quantum rods, or phosphors. For ease of description, a case where the first wavelength shifters 332 are quantum dots will be described below. The quantum dots may be particulate materials that emit light of a given color in case electrons transit from a conduction band to a valence band. The quantum dots may be semiconductor nanocrystalline materials. The quantum dots may have a given band gap according to their composition and size. Thus, the quantum dots may absorb light and emit light having a unique wavelength. Examples of semiconductor nanocrystals of the quantum dots include group IV nanocrystals, group II-VI compound nanocrystals, group III-V compound nanocrystals, group IV-VI nanocrystals, and combinations thereof.

The group II-VI compounds may be selected from binary compounds selected from CdSe, CdTe, ZnS, ZnSe, ZnTe, ZnO, HgS, HgSe, HgTe, MgSe, MgS and mixtures thereof; ternary compounds selected from InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and quaternary compounds selected from HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compounds may be selected from binary compounds selected from GaN, GaP, GaAs, GaSb, AlN, AlP, AlAs, AlSb, InN, InP, InAs, InSb and mixtures thereof; ternary compounds selected from GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and mixtures thereof; and quaternary compounds selected from GaAlNAs, GaAlNSb, GaAlPAs, GaAlPSb, GaInNP, GaInNAs, GalInNSb, GaInPAs, GaInPSb, InAlNP, InAlNAs, InAlNSb, InAlPAs, InAlPSb and mixtures thereof.

The group IV-VI compounds may be selected from binary compounds selected from SnS, SnSe, SnTe, PbS, PbSe, PbTe and mixtures thereof; ternary compounds selected from SnSeS, SnSeTe, SnSTe, PbSeS, PbSeTe, PbSTe, SnPbS, SnPbSe, SnPbTe and mixtures thereof; and quaternary compounds selected from SnPbSSe, SnPbSeTe, SnPbSTe and mixtures thereof. The group IV elements may be selected from silicon (Si), germanium (Ge), and a mixture thereof. The group IV compounds may be binary compounds selected from silicon carbide (SIC), silicon germanium (SiGe), and a mixture thereof.

Here, the binary, ternary or quaternary compounds may be present in particles at a uniform concentration or may be present in the same particles at partially different concentrations. They may have a core/shell structure in which one quantum dot surrounds another quantum dot. An interface between the core and the shell may have a concentration gradient in which the concentration of an element present in the shell is reduced toward the center.

In an embodiment, the quantum dots may have a core-shell structure including a core containing the above-described nanocrystal and a shell surrounding the core. The shell of each quantum dot may serve as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of an element present in the shell is reduced toward the center. The shell of each quantum dot may be, for example, a metal or non-metal oxide, a semiconductor compound, or a combination thereof.

For example, the metal or non-metal oxide may be, but is not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ or NiO or a ternary compound such as MgAl₂O₄, CoFe₂O₄, NiFe₂O₄ or CoMn₂O₄.

The semiconductor compound may be, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb.

Light emitted from the first wavelength shifters 332 may have a full width of half maximum (FWHM) of an emission wavelength spectrum of about 45 nm or less, about 40 nm or less, or about 30 nm or less. Therefore, the color purity and color reproducibility of the display device 1 can be further improved. The light emitted from the first wavelength shifters 332 may be radiated in various directions regardless of the incident direction of incident light. Therefore, the lateral visibility of the second color displayed in the second light transmitting area TA2 can be improved.

A portion of the output light LE provided by the second light emitting element may be transmitted through the second light transmitting member WCL1 without being converted into green light by the first wavelength shifters 332. Of the output light LE, a component incident on the second filtering pattern area 322a of the second color filter CF2 without being wavelength-converted by the second light transmitting member WCL1 may be blocked by the second filtering pattern area 322a. On the other hand, green light into which the output light LE has been converted by the second light transmitting member WCL1 may be transmitted through the second filtering pattern area 322a and emitted to the outside. For example, the second output light L2 emitted to the outside of the display device 1 through the second light transmitting area TA2 may be green light.

The third light transmitting member WCL2 may be disposed in a space defined by the bank member BK and may overlap the third light emitting area EA3 and the third light transmitting area TA3 in the third direction DR3. The third light transmitting member WCL2 may directly contact the second capping layer CPL2 and the bank member BK.

The third light transmitting member WCL2 may be a wavelength converting pattern that converts or shifts a peak wavelength of incident light into another given peak wavelength and outputs light having the given peak wavelength. For example, the output light LE provided by the third light emitting element may be blue light as described above and may be converted into red light having a peak wavelength in the range of about 610 to about 650 nm as it passes through the third light transmitting member WCL2 and the third filtering pattern area 323a of the third color filter CF3. Accordingly, the red light may be emitted to the outside of the display device 1. In other words, third output light L3 emitted from the third light emitting area EA3 to the outside through the third light transmitting area TA3 may be red light.

The third light transmitting member WCL2 may include a base resin 330, light scatterers 331 dispersed in the base resin 330, and second wavelength shifters 333 dispersed in the base resin 330.

The second wavelength shifters 333 may convert or shift a peak wavelength of incident light to another given peak wavelength. The second wavelength shifters 333 may convert the output light LE, which is blue light provided by the third light emitting element, into red light having a single peak wavelength in the range of about 610 to about 650 nm and output the red light. In an embodiment, the second wavelength shifters 333 may be, but are not limited to, quantum dots, quantum rods, or phosphors. In case that the second wavelength shifters 333 are quantum dots, they may have substantially the same composition as the above-described first wavelength shifters 332 in case that the first wavelength shifters 332 are quantum dots. Therefore, a description of the second wavelength shifters 333 will be omitted.

A portion of the output light LE provided by the third light emitting element may be transmitted through the second light transmitting member WCL2 without being converted into red light by the second wavelength shifters 333. Of the output light LE, a component incident on the third filtering pattern area 323a of the third color filter CF3 without being wavelength-converted by the third light transmitting member WCL2 may be blocked by the third filtering pattern area 323a. On the other hand, red light into which the output light LE has been converted by the third light transmitting member WCL2 may be transmitted through the third filtering pattern area 323a and emitted to the outside. For example, the third output light L3 emitted to the outside of the display device 1 through the third light transmitting area TA3 may be red light.

The third capping layer CPL3 of the light transmitting unit 300 may be disposed on the bank member BK, the first light transmitting member TPL, the second light transmitting member WCL1 and the third light transmitting member WCL2 to prevent damage to or contamination of the first light transmitting member TPL, the second light transmitting member WCL1 and the third light transmitting member WLC2 by preventing penetration of impurities such as moisture or air from the outside into the first light transmitting member TPL, the second light transmitting member WCL1 and the third light transmitting member WCL2. The third capping layer CPL3 may cover the first light transmitting member TPL, the second light transmitting member WCL1, and the third light transmitting member WCL2.

The filler 500 may be between the light emitting unit 100 and the light transmitting unit 300 to fill the space between the light emitting unit 100 and the light transmitting unit 300 as described above. For example, in an embodiment, the filler 500 may directly contact the upper inorganic layer TFEc of the thin-film encapsulation layer TFE of the light emitting unit 100 and the third capping layer CPL3 of the light transmitting unit 300. However, the disclosure is not limited thereto.

In an embodiment, the filler 500 may be made of a material having an extinction coefficient of substantially zero. A refractive index and an extinction coefficient are correlated, and the extinction coefficient decreases as the refractive index decreases. In case that the refractive index is 1.7 or less, the extinction coefficient may converge to substantially zero. In an embodiment, the filler 500 may be made of a material having a refractive index of 1.7 or less. Accordingly, light provided by the self-light emitting elements can be prevented from being absorbed by the filler 500 as it passes through the filler 500, or the absorption of the light by the filler 500 can be minimized. In an embodiment, the filler 500 may be made of an organic material having a refractive index of 1.4 to 1.6.

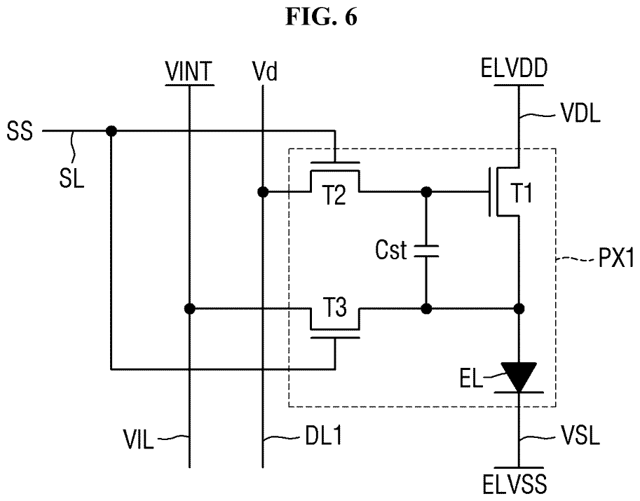

FIG. 6 is a schematic diagram of an equivalent circuit of the first pixel PX1 of the display device 1 according to the embodiment.

Referring to FIG. 6, the first pixel PX1 of the display device 1 according to the embodiment may include a light emitting element EL, transistors T1 through T3, and a storage capacitor Cst.

The light emitting element EL emits light according to a current supplied through a first transistor T1. The light emitting element EL may include a first electrode (for example, an anode), a second electrode (for example, a cathode), and at least one light emitting element EL disposed between them. The light emitting element may emit light in a given wavelength range in response to electrical signals received from the first electrode and the second electrode.

One end of the light emitting element EL may be connected to a source electrode of the first transistor T1, and the other end may be connected to a common voltage line VSL to which a common voltage ELVSS lower than a driving voltage ELVDD of a driving voltage line VDL is supplied.

The first transistor T1 may adjust a current flowing from the driving voltage line VDL, to which a first power supply voltage is supplied, to the light emitting element EL according to a voltage difference between a gate electrode and the source electrode. For example, the first transistor T1 may be a driving transistor for driving the light emitting element EL. The first transistor T1 may have the gate electrode connected to a source electrode of a second transistor T2, the source electrode connected to the first electrode of the light emitting element EL, and a drain electrode connected to the driving voltage line VDL to which the first power supply voltage is applied.

The second transistor T2 may be turned on by a scan signal SS of a scan line SL to connect a first data line DL1 to the gate electrode of the first transistor T1. The second transistor T2 may have a gate electrode connected to the scan line SL, the source electrode connected to the gate electrode of the first transistor T1, and a drain electrode connected to the first data line DL1. A data voltage Vd may be applied to the first data line DL1.

A third transistor T3 may be turned on by the scan signal SS of the scan line SL to connect an initialization voltage line VIL to the one end of the light emitting element EL to supply an initialization voltage VINT. The third transistor T3 may have a gate electrode connected to the scan line SL, a drain electrode connected to the initialization voltage line VIL, and a source electrode connected to the one end of the light emitting element EL or the source electrode of the first transistor T1.

In an embodiment, the source electrode and the drain electrode of each of the transistors T1 through T3 are not limited to the above description, and the opposite may also be the case. Each of the transistors T1 through T3 may be formed as a thin-film transistor. Although a case where each of the transistors T1 through T3 is an N-type metal oxide semiconductor field effect transistor (MOSFET) has been described in FIG. 6, the disclosure is not limited thereto. For example, each of the transistors T1 through T3 may also be formed as a P-type MOSFET, or some of them may be formed as N-type MOSFETs, and the other may be formed as a P-type MOSFET.

The storage capacitor Cst is formed between the gate electrode and the source electrode of the first transistor T1. The storage capacitor Cst stores a difference between a gate voltage and a source voltage of the first transistor T1.

In the embodiment of FIG. 6, the gate electrodes of the second transistor T2 and the third transistor T3 are connected to the same scan line SL. Therefore, the second transistor T2 and the third transistor T3 are simultaneously turned on by a scan signal transmitted from the same scan line. However, the disclosure is not limited to this case. The gate electrode of the second transistor T2 may be connected to any one scan line SL, and the gate electrode of the third transistor T3 may be connected to another scan lines SL different from the above scan line SL.

The second pixel PX2 and the third pixel PX3 may have the same circuit structure as the first pixel PX1 of FIG. 6.

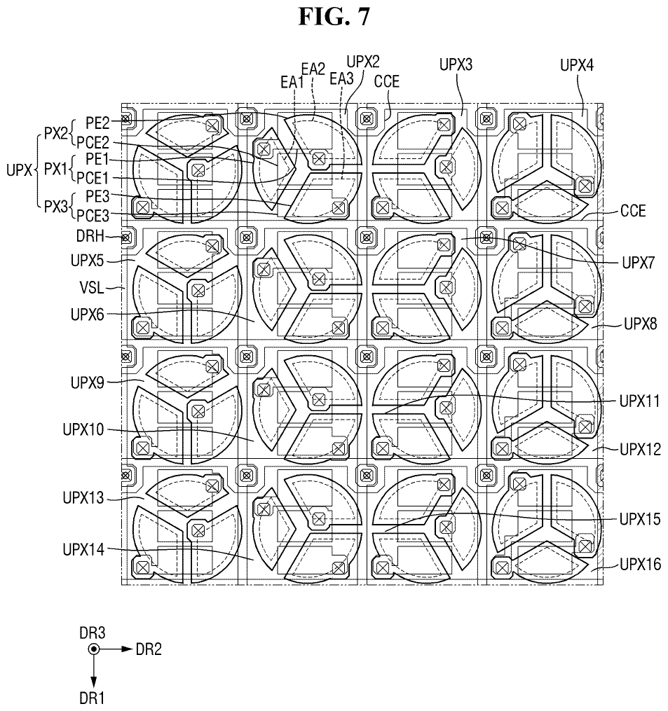

FIG. 7 is a schematic plan view of the display device 1 according to the embodiment.

As illustrated in FIG. 7, the display device 1 may include unit pixels UPX (e.g., UPX1 through UPX16). The unit pixels UPX1 through UPX16 may be respectively disposed in areas (hereinafter, referred to as unit areas) surrounded and defined by common voltage lines VSL and common connection electrodes CCE intersecting each other. For example, unit areas may be defined by the common voltage lines VSL extending along the first direction DR1 and arranged (or disposed) along the second direction DR2 and the common connection electrodes CCE extending along the second direction DR2 and arranged along the first direction DR1. Therefore, the unit pixels UPX1 through UPX16 may be disposed in the unit areas, respectively. According to an embodiment, in FIG. 7, sixteen unit pixels UPX1 through UPX16 are disposed in sixteen unit areas, respectively. The common voltage lines VSL and the common connection electrodes CCE may be connected to each other through drilling holes DRH at their intersection points.

A unit pixel (for example, UPX2) may include the first pixel PX1, the second pixel PX2, and the third pixel PX3 disposed adjacent to each other. In other words, the first pixel PX1, the second pixel PX2, and the third pixel PX3 adjacent to each other may form one unit pixel.

The first pixel PX1 may include the first pixel electrode PE1 and a first pixel connection electrode PCE1. The first pixel connection electrode PCE1 may connect the first pixel electrode PE1 and the first transistor T1 of the first pixel PX1. The first pixel electrode PE1 may be connected to the first pixel connection electrode PCE1 through a contact hole in an insulating layer. The first pixel electrode PE1 may be disposed to correspond to the first light emitting area EA1 defined by the pixel defining layer PDL. The pixel defining layer PDL may overlap edges of the first pixel electrode PE1. At least a portion of the first pixel electrode PE1 may have a round shape. For example, the first pixel electrode PE1 may have a fan shape in plan view.

The second pixel PX2 may include the second pixel electrode PE2 and a second pixel connection electrode PCE2. The second pixel connection electrode PCE2 may connect the second pixel electrode PE2 and a first transistor T1 of the second pixel PX2. The second pixel electrode PE2 may be connected to the second pixel connection electrode PCE2 through a contact hole in the insulating layer. The second pixel electrode PE2 may be disposed to correspond to the second light emitting area EA2 defined by the pixel defining layer PDL. The pixel defining layer PDL may overlap edges of the second pixel electrode PE2. At least a portion of the second pixel electrode PE2 may have a round shape. For example, the second pixel electrode PE2 may have a fan shape in plan view.

The third pixel PX3 may include the third pixel electrode PE3 and a third pixel connection electrode PCE3. The third pixel connection electrode PCE3 may connect the third pixel electrode PE3 and a first transistor T1 of the third pixel PX3. The third pixel electrode PE3 may be connected to the third pixel connection electrode PCE3 through a contact hole in the insulating layer. The third pixel electrode PE3 may be disposed to correspond to the third light emitting area EA3 defined by the pixel defining layer PDL. The pixel defining layer PDL may overlap edges of the third pixel electrode PE3. At least a portion of the third pixel electrode PE3 may have a round shape. For example, the third pixel electrode PE3 may have a fan shape in plan view.

The first pixel electrode PE1, the second pixel electrode PE2, and the third pixel electrode PE3 included in one unit pixel (for example, UPX2) may form a roughly circular shape. For example, pixel electrodes included in one unit pixel may each have a fan shape. In this case, a curve extending along arcs of the pixel electrodes included in the unit pixel may form a circle.

In an embodiment, a central angle of each of the first pixel electrode PE1, the second pixel electrode PE2, and the third pixel electrode PE3 may be 120 degrees. However, the central angle of each of the pixel electrodes PE1 through PE3 is not limited thereto and may vary according to the shape and position of the pixel electrode PE1, PE2 or PE3.

In an embodiment, at least a portion of the first light emitting area EA1, at least a portion of the second light emitting area EA2, and at least a portion of the third light emitting area EA3 described above may have a round shape. For example, each of the first light emitting area EA1, the second light emitting area EA2, and the third light emitting area EA3 may have a fan shape.

In an embodiment, a central angle of each of the first light emitting area EA1, the second light emitting area EA2, and the third light emitting area EA3 may be 120 degrees. However, the central angle of each of the light emitting areas EA1 through EA3 is not limited thereto and may vary according to the shape and position of the light emitting area EA1, EA2 or EA3.

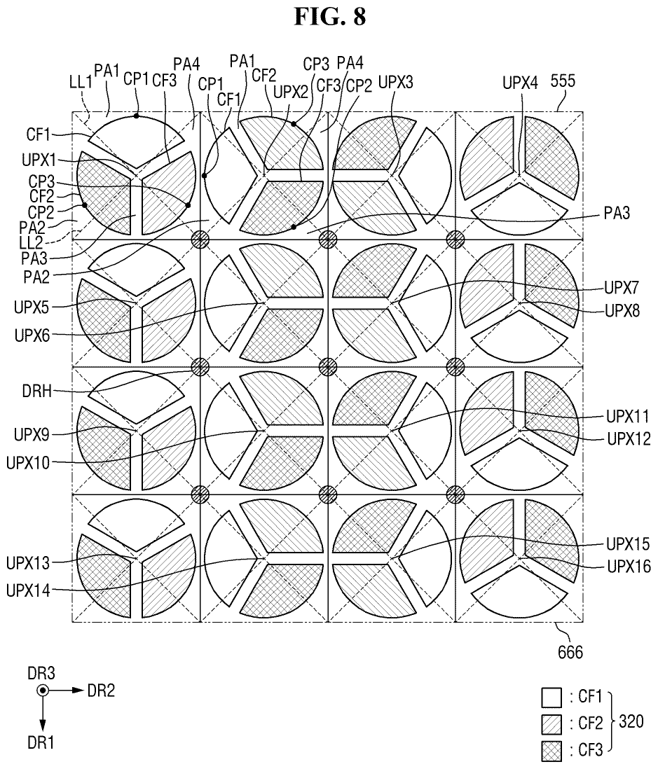

FIG. 8 is a schematic plan view of the color filter member 320 disposed to correspond to each unit pixel of FIG. 7.

As illustrated in FIG. 8, each unit pixel of the display device 1 may include the color filter member 320. For example, sixteen color filter members 320 arranged to respectively correspond to sixteen unit pixels UPX1 through UPX16 are illustrated in FIG. 8.

Each of the color filter members 320 may include the first color filter CF1, the second color filter CF2, and the third color filter CF3 disposed adjacent to each other. In other words, the first color filter CF1, the second color filter CF2, and the third color filter CF3 adjacent to each other may form each of the color filter members 320.

The first color filter CF1 may be a blue color filter that transmits the first light (for example, blue light) described above. At least a portion of the first color filter CF1 may have a round shape. For example, the first color filter CF1 may have a fan shape in plan view. The first color filter CF1 may be disposed to correspond to the first pixel electrode PE1 and the first light emitting area EA1 described above. The first color filter CF1, the first pixel electrode PE1, and the first light emitting area EA1 may have fan shapes similar to each other.

The second color filter CF2 may be a green color filter that transmits the second light (for example, green light) described above. At least a portion of the second color filter CF2 may have a round shape. For example, the second color filter CF2 may have a fan shape in plan view. The second color filter CF2 may be disposed to correspond to the second pixel electrode PE2 and the second light emitting area EA2 described above. The second color filter CF2, the second pixel electrode PE2, and the second light emitting area EA2 may have fan shapes similar to each other.

The third color filter CF3 may be a red color filter that transmits the third light (for example, red light) described above. At least a portion of the third color filter CF3 may have a round shape. For example, the third color filter CF3 may have a fan shape in plan view. The third color filter CF3 may be disposed to correspond to the third pixel electrode PE3 and the third light emitting area EA3 described above. The third color filter CF3, the third pixel electrode PE3, and the third light emitting area EA3 may have fan shapes similar to each other.

In an embodiment, a central angle of each of the first color filter CF1, the second color filter CF2, and the third color filter CF3 may be 120 degrees. However, the central angle of each of the color filters CF1 through CF3 is not limited thereto and may vary according to the shape and position of the color filter CF1, CF2 or CF3.

In an embodiment, the same color filters of adjacent unit pixels may be disposed in different areas, as described in detail below.

For example, each of the unit pixels UPX1 through UPX16 may have a square shape. A unit pixel (for example, UPX1) may be divided into four pixel areas PA1 through PA4 by an imaginary first diagonal line LL1 connecting two vertices facing each other in a diagonal direction among four vertices of the unit pixel and an imaginary second diagonal line LL2 connecting the other two vertices in a diagonal direction. For example, each unit pixel may include a first pixel area PA1 disposed on an upper side of the unit pixel, a second pixel area PA2 disposed on a left side of the unit pixel, a third pixel area PA3 disposed on a lower side of the unit pixel, and a fourth pixel area PA4 disposed on a right side of the unit pixel. Each of the pixel areas PA1 through PA4 may have a triangular shape.

Among the color filters of unit pixels adjacent to each other in one direction (for example, the second direction DR2), color filters of the same color may have centers (for example, centers of arcs) disposed in different pixel areas. Here, a center of an arc refers to a center of an arc of a fan-shaped color filter. For example, a first unit pixel UPX1 and a second unit pixel UPX2 are disposed adjacent to each other in the second direction DR2. Here, a center CP1 of an arc of the first color filter CF1 in the first unit pixel UPX1 may be disposed in the first pixel area PA1, and a center CP1 of an arc of the first color filter CF1 in the second unit pixel UPX2 may be disposed in the second pixel area PA2. A center CP2 of an arc of the second color filter CF2 in the first unit pixel UPX1 may be disposed in the fourth pixel area PA4, and a center CP2 of an arc of the second color filter CF2 in the second unit pixel UPX2 may be disposed in the first pixel area PA1. A center CP3 of an arc of the third color filter CF3 in the first unit pixel UPX1 may be disposed in the second pixel area PA2, and a center CP3 of an arc of the third color filter CF3 in the second unit pixel UPX2 may be disposed in the third pixel area PA3.

According to an embodiment, the color filter members 320 of unit pixels adjacent to each other in one direction (for example, the second direction DR2) may have different shapes. In other words, positions of the color filters CF1 through CF3 in unit pixels adjacent to each other in the direction may be different from each other. For example, the first unit pixel UPX1 and the second unit pixel UPX2 may be disposed adjacent to each other in the second direction DR2. Here, the color filter member 320 of the second unit pixel UPX2 may have a shape rotated 90 degrees counterclockwise with respect to the color filter member 320 of the first unit pixel UPX1. For example, the first color filter CF1 of the second unit pixel UPX2 may have a shape rotated 90 degrees counterclockwise with respect to the first color filter CF1 of the first unit pixel UPX1. As an example, an imaginary line connecting the center of the arc of the first color filter CF1 disposed in the first unit pixel UPX1 and a center of the first color filter CF1 disposed in the first unit pixel UPX1 (for example, a portion to which two line segments defining the central angle of the first color filter CF1 disposed in the first unit pixel UPX1 are connected) may be defined as a first center line. An imaginary line connecting the center of the arc of the first color filter CF1 disposed in the second unit pixel UPX2 and a center of the first color filter CF1 disposed in the second unit pixel UPX2 (for example, a portion to which two line segments defining the central angle of the first color filter CF1 disposed in the second unit pixel UPX2 are connected) may be defined as a second center line. In this case, an angle formed by the first center line and the second center line may be about 90 degrees. For example, an angle between an imaginary first line extending along the first center line and an imaginary second line extending along the second center line may be about 90 degrees. Accordingly, as in the above-described example, while the center of the arc of the first color filter CF1 disposed in the first unit pixel UPX1 is disposed in the first pixel area PA1 of the first unit pixel UPX1, the center of the arc of the first color filter CF1 disposed in the second unit pixel UPX2 may be disposed in the second pixel area PA2 of the second unit pixel UPX2.

According to an embodiment, as in the example illustrated in FIG. 8, the color filter member 320 of a third unit pixel UPX3 may have a shape rotated about 180 degrees counterclockwise with respect to the color filter member 320 of the second unit pixel UPX2. As an example, an imaginary line connecting the center of the arc of the first color filter CF1 disposed in the second unit pixel UPX2 and the center of the first color filter CF1 disposed in the second unit pixel UPX2 may be defined as a third center line. An imaginary line connecting a center of an arc of the first color filter CF1 disposed in the third unit pixel UPX3 and a center of the first color filter CF1 disposed in the third unit pixel UPX3 may be defined as a fourth center line. In this case, an angle formed by the third center line and the fourth center line may be about 180 degrees. For example, an angle between an imaginary third line extending along the third center line and an imaginary fourth line extending along the fourth center line may be about 180 degrees.

According to an embodiment, the color filter member 320 of a fourth unit pixel UPX4 may have a shape rotated about 90 degrees clockwise with respect to the color filter member 320 of the third unit pixel UPX3.

According to an embodiment, the color filter members 320 of unit pixels adjacent to each other in another direction (for example, the first direction DR1) intersecting the above one direction may have the same shape. In other words, color filters in the color filter members 320 of unit pixels adjacent to each other in another direction may be disposed identically to each other. For example, since the first unit pixel UPX1 and a fifth unit pixel UPX5 are disposed adjacent to each other in the first direction DR1, the color filter member 320 of the fifth unit pixel UPX5 may have the same shape as the color filter member 320 of the first unit pixel UPX1. For example, the first color filter CF1 of the fifth unit pixel UPX5 and the first color filter CF1 of the first unit pixel UPX1 may have the same shape and face the same direction. As in the example illustrated in FIG. 8, the color filter members 320 of unit pixels disposed along the first direction DR1 may have the same shape.

As illustrated in FIG. 8, in case that the first through sixteenth unit pixels UPX1 through UPX16 arranged in a 4×4 matrix form are defined as a unit pixel group, the display device 1 may include unit pixel groups. For example, the unit pixel group of FIG. 8 may be repeated along the second direction DR2 and may be repeated along the first direction DR1.

As described above, the arrangement of color filters is different in unit pixels adjacent to each other in one direction (for example, the second direction DR2). Therefore, color filters facing an upper edge 555 (for example, an edge extending along the second direction DR2) of the unit pixel group may have various colors, thereby minimizing a color fringing phenomenon. For example, the color filters facing (or adjacent to) the upper edge 555 of the unit pixel group may include the first color filter CF1 of the first unit pixel UPX1, the first color filter CF1 and the second color filter CF2 of the second unit pixel UPX2, the first color filter CF1 and the third color filter CF3 of the third unit pixel UPX3, and the second color filter CF2 and the third color filter CF3 of the fourth unit pixel UPX4. In other words, the color filters facing the upper edge 555 of the unit pixel group may include the color (for example, blue) of the first color filter CF1, the color (for example, green) of the second color filter CF2, and the color (for example, red) of the third color filter CF3. Since color filters of various colors are evenly disposed at the upper edge 555 of the unit pixel group, blue light, green light, and red light may be evenly distributed at the upper edge 555 of the unit pixel group. According to an embodiment, since color filters of various colors are evenly disposed at a lower edge 666 of the unit pixel group, blue light, green light, and red light may be evenly distributed at the lower edge 666 of the unit pixel group. Therefore, according to an embodiment, it is possible to minimize the color fringing phenomenon (such as bluish and greenish) which may occur in a structure in which color filters of one color are disposed along the upper edge 555 or the lower edge 666 of the unit pixel group. The display device 1 according to the embodiment may have, for example, a color fringing index of about 0.6.

For example, in case that a full white box pattern of a selectable size is displayed on a full black background, the color fringing phenomenon can be found at an upper edge of the box pattern or a lower edge of the box pattern.

According to an embodiment, each light transmitting member may have the same shape as the color filter described above. For example, the first light transmitting member TPL may have the same fan shape as the first color filter CF1, the second light transmitting member WCL1 may have the same fan shape as the second color filter CF2, and the third light transmitting member WCL2 may have the same fan shape as the third color filter CF3.

According to an embodiment, each drilling hole DRH to be described later may be disposed between adjacent unit pixels. For example, each drilling hole DRH may be disposed at a center of a group of four adjacent unit pixels.

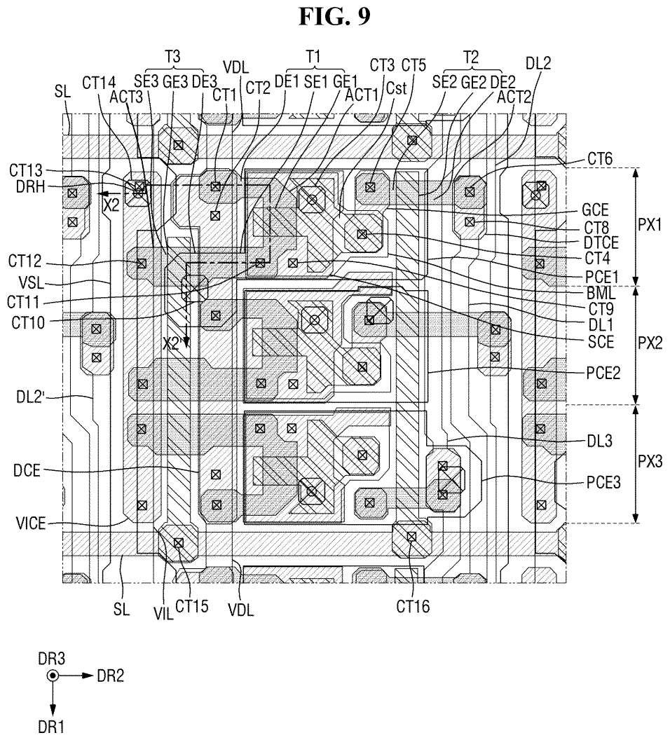

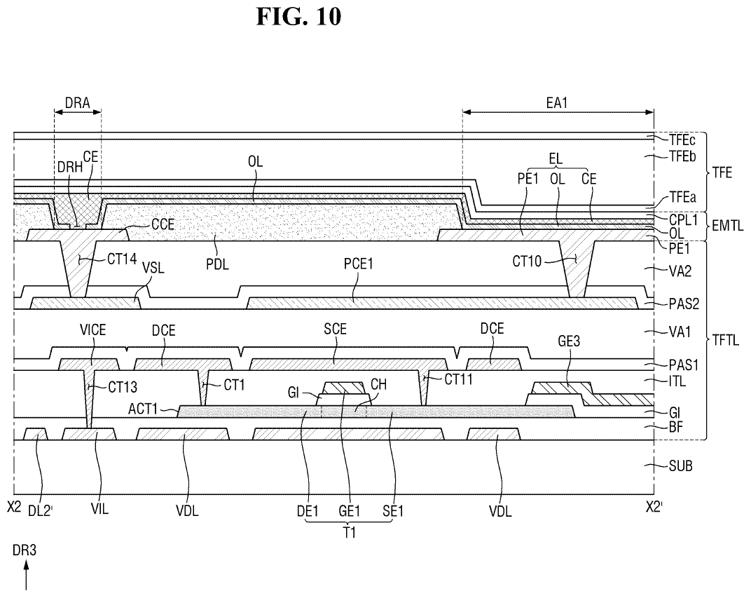

FIG. 9 is an array view of the display device 1 according to the embodiment. FIG. 10 is a schematic cross-sectional view taken along line X2-X2′ of FIG. 9. Here, FIG. 9 may be, for example, an array view of the second unit pixel UPX2 of FIGS. 7 and 8 described above.

As illustrated in FIG. 9, each of the first pixel PX1, the second pixel PX2, and the third pixel PX3 may include a first transistor T1, a second transistor T2, a third transistor T3, and a storage capacitor Cst as described above.

The second transistor T2 of the first pixel PX1 may be connected to a first data line DL1, the second transistor T2 of the second pixel PX2 may be connected to a second data line DL2, and the second transistor T2 of the third pixel PX3 may be connected to a third data line DL3.

Since the array structures of the first pixel PX1, the second pixel PX2, and the third pixel PX3 are the same, the array structure of the first pixel PX1 will be described below as a representative example.

As illustrated in FIGS. 9 and 10, the display device 1 may include the substrate SUB, a thin-film transistor layer TFTL, a light emitting element layer EMTL, and the thin-film encapsulation layer TFE. The thin-film transistor layer TFTL, the light emitting element layer EMTL, and the thin-film encapsulation layer TFE may be sequentially disposed on the substrate SUB along the third direction DR3. Here, the thin-film transistor layer TFTL may include the first transistor T1, the second transistor T2, the third transistor T3, and the storage capacitor Cst described above.

The substrate SUB may be a rigid substrate or a flexible substrate that can be bent, folded, or rolled. The substrate SUB may be made of an insulating material such as glass, quartz, or polymer resin. The polymer material may be, for example, polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or a combination thereof. By way of example, the first substrate SUB may include a metal material.

A first pattern layer may be disposed on the substrate SUB. The first pattern layer may include, for example, the first data line DL1, an initialization voltage line VIL, and a driving voltage line VDL. Reference character ‘DL2’ indicates a data line connected to another pixel.

The first data line DL1 may extend along the first direction DR1.

A light blocking layer BML may be made of, for example, a metal material such as chromium (Cr) or molybdenum (Mo), black ink, or black dye. In case that the light blocking layer BML is made of a metal material, it may be supplied with static power. Accordingly, the light blocking layer BML may not float electrically, and the electrical characteristics of transistors on the light blocking layer BML can be stabilized.

The initialization voltage line VIL may extend along the first direction DR1.

The buffer layer BF may be disposed on the first pattern layer. For example, as in the example illustrated in FIG. 10, the buffer layer BF may be disposed on the first data line DL1, the initialization voltage line VIL, and the driving voltage line VDL. The buffer layer BF may be a layer for protecting the transistors T1 through T3 of the thin-film transistor layer TFTL and the light emitting layer OL of the light emitting element layer EMTL from moisture introduced through the substrate SUB which is vulnerable to moisture penetration. The buffer layer BF may be composed of inorganic layers stacked each other alternately. For example, the buffer layer BF may be a multilayer in which one or more inorganic layers selected from a silicon nitride layer, a silicon oxynitride layer, a silicon oxide layer, a titanium oxide layer, and an aluminum oxide layer are alternately stacked each other.

A second pattern layer may be disposed on the buffer layer BF. The second pattern layer may include a first active layer ACT1 and a second active layer ACT2 as illustrated in FIGS. 9 and 10. The first active layer ACT1 and the second active layer ACT2 may overlap the first pattern layer thereunder. For example, as illustrated in FIG. 10, the first active layer ACT1 may be disposed on the buffer layer BF to overlap the light blocking layer BML and the driving voltage line VDL.

The first active layer ACT1 and the second active layer ACT2 may be active layers made of low-temperature polycrystalline silicon (LTPS). The first active layer ACT1 and the second active layer ACT2 may be oxide-based active layers. For example, each of the first active layer ACT1 and the second active layer ACT2 may be an oxide semiconductor including indium-gallium-zinc-oxide (IGZO) or indium-gallium-zinc-tin oxide (IGZTO).

A gate insulating layer GI may be disposed on the second pattern layer. For example, as illustrated in FIG. 10, the gate insulating layer GI may be disposed on the first active layer ACT1.

The gate insulating layer GI may include at least one of tetraethylorthosilicate (TEOS), silicon nitride (SiNₓ), and silicon oxide (SiO₂). For example, the gate insulating layer GI may have a double-layer structure in which a silicon nitride layer with a thickness of about 40 nm and a tetraethylorthosilicate layer with a thickness of about 80 nm are sequentially stacked each other.

A third pattern layer may be disposed on the gate insulating layer GI. As illustrated in FIGS. 9 and 10, the third pattern layer may include a first gate electrode GE1, a second gate electrode GE2, and a third gate electrode GE3. The first gate electrode GE1 and the third gate electrode GE3 may be disposed on the gate insulating layer GI to overlap the first active layer ACT1, and the second gate electrode GE2 may be disposed on the gate insulating layer GI to overlap the second active layer ACT2.

The first gate electrode GE1 may overlap the light blocking layer BML with the gate insulating layer GI and the buffer layer BF disposed between them. A first storage capacitor Cst may be formed in a portion of the first gate electrode GE1 which overlaps the light blocking layer BML described above. In other words, the first storage capacitor may be disposed between the first gate electrode GE1 and the light blocking layer BML.

A portion of the first active layer ACT1 which is overlapped by the first gate electrode GE1 may be a channel region CH of the first transistor T1, and portions of the first active layer ACT1 which are not overlapped by the first gate electrode GE1 and separated by the first gate electrode GE1 in plan view may be a first drain electrode DE1 and a first source electrode SE1 of the first transistor T1, respectively.

A portion of the first active layer ACT1 which is overlapped by the third gate electrode GE3 may be a channel region of the third transistor T3, and portions of the first active layer ACT1 which are not overlapped by the third gate electrode GE3 and separated by the third gate electrode GE3 in plan view may be a third drain electrode DE3 and a third source electrode SE3 of the third transistor T3, respectively.

A portion of the second active layer ACT2 which is overlapped by the second gate electrode GE2 may be a channel region of the second transistor T2, and portions of the second active layer ACT2 which are not overlapped by the second gate electrode GE2 and separated by the second gate electrode GE2 in plan view may be a second drain electrode DE2 and a second source electrode SE2 of the second transistor T2, respectively.

A portion of a third active layer ACT3 which is overlapped by the third gate electrode GE3 may be a channel region of the third transistor T3, and portions of the third active layer ACT3 which are not overlapped by the third gate electrode GE3 and separated by the third gate electrode GE3 in plan view may be a third drain electrode DE3 and a third source electrode SE3 of the third transistor T3, respectively.

An interlayer insulating layer ITL may be disposed on the third pattern layer. For example, as illustrated in FIG. 10, the interlayer insulating layer ITL may be disposed on the first gate electrode GE1.

The interlayer insulating layer ITL may include an inorganic layer, for example, a silicon nitride layer, a silicon oxynitride layer, a silicon oxide layer, a titanium oxide layer, or an aluminum oxide layer. The interlayer insulating layer ITL may include inorganic layers.

A fourth pattern layer may be disposed on the interlayer insulating layer ITL. As illustrated in FIGS. 9 and 10, the fourth pattern layer may include a gate connection electrode GCE, a drain connection electrode DCE, a source connection electrode SCE, a data connection electrode DTCE, an initialization connection electrode VICE, and a scan line SL.

The gate connection electrode GCE may be connected to the first gate electrode GE1 of the first transistor T1 through a fourth contact hole CT4 penetrating the interlayer insulating layer ITL. The gate connection electrode GCE may be connected to the second source electrode SE2 of the second transistor T2 through a fifth contact hole CT5 penetrating the interlayer insulating layer ITL.

The drain connection electrode DCE may be connected to the first drain electrode DE1 of the first transistor T1 through a first contact hole CT1 penetrating the interlayer insulating layer ITL. The drain connection electrode DCE may be connected to the driving voltage line VDL through a second contact hole CT2 penetrating the interlayer insulating layer ITL and the buffer layer BF.

The source connection electrode SCE may be connected to the first source electrode SE1 of the first transistor T1 through an eleventh contact hole CT11 penetrating the interlayer insulating layer ITL. The source connection electrode SCE may be connected to the light blocking layer BML through a ninth contact hole CT9 penetrating the interlayer insulating layer ITL and the buffer layer BF. The source connection electrode SCE may overlap the first gate electrode GE1 with the interlayer insulating layer ITL between them. A second storage capacitor may be formed in a portion of the source connection electrode SCE which overlaps the first gate electrode GE1. In other words, the second storage capacitor may be disposed between the source connection electrode SCE and the first gate electrode GE1. The storage capacitor Cst described above may include the first storage capacitor and the second storage capacitor.

The data connection electrode DTCE may be connected to the first data line DL1 through an eighth contact hole CT8 penetrating the interlayer insulating layer ITL and the buffer layer BF. The data connection electrode DTCE may be connected to the second drain electrode DE2 of the second transistor T2 through a sixth contact hole CT6 penetrating the interlayer insulating layer ITL.

The initialization connection electrode VICE may be connected to the initialization voltage line VIL through a thirteenth contact hole CT13 penetrating the interlayer insulating layer ITL and the buffer layer BF. The initialization connection electrode VICE may be connected to the third source electrode SE3 of the third transistor T3 through a twelfth contact hole CT12 penetrating the interlayer insulating layer ITL.

The scan line SL may be connected to the third gate electrode GE3 through a fifteenth contact hole CT15 penetrating the interlayer insulating layer ITL. The scan line SL may be connected to the second gate electrode GE2 through a sixteenth contact hole CT16 penetrating the interlayer insulating layer ITL.

A first passivation layer PAS1 may be disposed on the fourth pattern layer. For example, as illustrated in FIG. 10, the first passivation layer PAS1 may be disposed on the initialization connection electrode VICE, the drain connection electrode DCE, and the source connection electrode SCE. The first passivation layer PAS1 may include an inorganic layer.

A first planarization layer VA1 may be disposed on the first passivation layer PAS1. The first planarization layer VA1 may include an organic layer such as acryl resin, epoxy resin, phenolic resin, polyamide resin, or polyimide resin.

A fifth pattern layer may be disposed on the first planarization layer VA1. As illustrated in FIGS. 9 and 10, the fifth pattern layer may include a first pixel connection electrode PCE1 and a common voltage line VSL.

The first pixel connection electrode PCE1 may be connected to the source connection electrode SCE through a third contact hole CT3 penetrating the first planarization layer VA1 and the first passivation layer PAS1.

The common voltage line VSL may extend along the first direction DR1.

A second passivation layer PAS2 may be disposed on the fifth pattern layer. For example, as illustrated in FIG. 10, the second passivation layer PAS2 may be disposed on the first pixel connection electrode PCE1 and the common voltage line VSL. The second passivation layer PAS2 may include a same material as the first passivation layer PAS1 described above.

A second planarization layer VA2 may be disposed on the second passivation layer PAS2. The second planarization layer VA2 may include a same material as the first planarization layer VA1 described above.

The light emitting element layer EMTL including a sixth pattern layer may be disposed on the second planarization layer VA2. Here, the light emitting element layer EMTL may include a first pixel electrode PE1, a light emitting layer OL, and a common electrode CE. As in the example illustrated in FIGS. 9 and 10, the sixth pattern layer may include the first pixel electrode PE1 and a common connection electrode CCE.

The first pixel electrode PE1 may be connected to the first pixel connection electrode PCE1 through a tenth contact hole CT10 penetrating the second planarization layer VA2 and the second passivation layer PAS2. In a top emission structure in which light is emitted from the light emitting layer OL toward the common electrode CE, the first pixel electrode PE1 may be formed as a single layer of molybdenum (Mo), titanium (Ti), copper (Cu) or aluminum (Al) or, in order to increase reflectivity, may be formed as a stacked structure (Ti/Al/Ti) of aluminum and titanium, a stacked structure (ITO/AV/ITO) of aluminum and indium tin oxide, an APC alloy, or a stacked structure (ITO/APC/ITO) of an APC alloy and indium tin oxide. The APC alloy may be an alloy of silver (Ag), palladium (Pd), and copper (Cu).

The common connection electrode CCE may be connected to the common voltage line VSL through a fourteenth contact hole CT14 penetrating the second planarization layer VA2 and the second passivation layer PAS2. The common connection electrode CCE may include a same material as the first pixel electrode PE1 described above. According to an embodiment, the common connection electrode CCE may extend in the second direction DR2 as in the example illustrated in FIG. 7. For example, the common connection electrode CCE may intersect the common voltage line VSL extending in the first direction DR1.

The pixel defining layer PDL may be disposed on the sixth pattern layer. For example, as illustrated in FIG. 10, the pixel defining layer PDL may be disposed on the first pixel electrode PE1 and the common connection electrode CCE. The pixel defining layer PDL may have an opening defining the first light emitting area EA1 and an opening defining a drilling area DRA.

The light emitting layer OL described above may be disposed on the pixel defining layer PDL. As described above, the light emitting layer OL may have a tandem structure that provides, for example, blue light. According to an embodiment, the light emitting layer OL may have a drilling hole DRH disposed in the drilling area DRA of the pixel defining layer PDL. The drilling hole DRH may penetrate the light emitting layer OL in the third direction DR3. The drilling hole DRH may be formed using, for example, a laser drilling method.

The common electrode CE may be disposed on the light emitting layer OL. The common electrode CE may be connected to the common connection electrode CCE through the drilling hole DRH penetrating the light emitting layer OL. Accordingly, the common electrode CE may be connected to the common voltage line VSL through the common connection electrode CCE. The common electrode CE may receive a common voltage ELVSS from the common voltage line VSL.

The first capping layer CPL1 described above may be disposed on the common electrode CE.

The thin-film encapsulation layer TFE described above may be disposed on the first capping layer CPL1. The thin-film encapsulation layer TFE may include the lower inorganic layer TFEa, the organic layer TFEb, and the upper inorganic layer TFEc sequentially stacked each other on the first capping layer CPL1.

A second pixel connection electrode PCE2 included in the second pixel PX2 may be connected to a source connection electrode included in the second pixel PX2 through a contact hole penetrating the first planarization layer VA1 and the first passivation layer PAS1. A third pixel connection electrode PCE3 included in the third pixel PX3 may be connected to a source connection electrode included in the third pixel PX3 through a contact hole penetrating the first planarization layer VA1 and the first passivation layer PAS1.

A second pixel electrode PE2 included in the second pixel PX2 may be connected to the second pixel connection electrode PCE2 through a contact hole penetrating the second planarization layer VA2 and the second passivation layer PAS2. A third pixel electrode PE3 included in the third pixel PX3 may be connected to the third pixel connection electrode PCE3 through a contact hole penetrating the second planarization layer VA2 and the second passivation layer PAS2.

In a display device according to the disclosure, a color fringing phenomenon is minimized, thereby improving image quality.

It will be understood by one of ordinary skill in the art to which the disclosure pertains that the disclosure may be implemented in other forms without changing the technical spirit or essential features of the disclosure. Therefore, it is to be understood that embodiments described above are illustrative rather than being restrictive. It is to be understood that the scope of the disclosure are defined by the claims and the detailed description described above and all modifications and alterations derived from the claims and their equivalents fall within the scope of the disclosure.

What is claimed is:

1. A display device comprising:
a pixel electrode disposed on a substrate;
a light emitting layer disposed on the pixel electrode;
a common electrode disposed on the light emitting layer; and
a color filter part disposed on the common electrode,
wherein the color filter part of a first unit pixel comprises:
a first color filter;
a second color filter; and
a third color filter having a substantially fan shape, the first unit pixel comprises:
a first pixel area;
a second pixel area;
a third pixel area; and
a fourth pixel area, and a center of an arc of the first color filter, a center of an arc of the second color filter and a center of an arc of the third color filter are disposed in different pixel areas.

2. The display device of claim 1, wherein the center of the arc of the first color filter, the center of the arc of the second color filter, and the center of the arc of the third color filter are respectively disposed in any three pixel areas among the first pixel area, the second pixel area, the third pixel area and the fourth pixel area.

3. The display device of claim 2, wherein the center of the arc of the first color filter, the center of the arc of the second color filter and the center of the arc of the third color filter are not disposed in any one of the first pixel area, the second pixel area, the third pixel area and the fourth pixel area.

4. The display device of claim 1, wherein
a second unit pixel adjacent to the first unit pixel in one direction comprises a first pixel area, a second pixel area, a third pixel area and a fourth pixel area,
a color filter part disposed in the second unit pixel comprises a first color filter, a second color filter and a third color filter having a substantially fan shape, and
the color filter part of the second unit pixel has a different shape from the color filter part of the first unit pixel in plan view.

5. The display device of claim 4, wherein the color filter part of the second unit pixel has a shape rotated at a selectable angle with respect to the color filter part of the first unit pixel.

6. The display device of claim 5, wherein the color filter part of the second unit pixel has a shape rotated about 90 degrees or about 180 degrees clockwise or counterclockwise with respect to the color filter part of the first unit pixel.

7. The display device of claim 4, wherein positions of the first color filter, the second color filter, and the third color filter included in the color filter part of the second unit pixel are different from positions of the first color filter, the second color filter, and the third color filter included in the color filter part of the first unit pixel.

8. The display device of claim 7, wherein the first color filter of the second unit pixel has a shape rotated at a selectable angle with respect to the first color filter of the first unit pixel.

9. The display device of claim 8, wherein the first color filter of the second unit pixel has a shape rotated about 90 degrees or about 180 degrees clockwise or counterclockwise with respect to the first color filter of the first unit pixel.

10. The display device of claim 4, wherein the center of the arc of the first color filter disposed in the first unit pixel and a center of an arc of the first color filter disposed in the second unit pixel are disposed in different pixel areas.

11. The display device of claim 10, wherein in case that an imaginary line connecting the center of the arc of the first color filter disposed in the first unit pixel and a center of the first color filter disposed in the first unit pixel is defined as a first center line and an imaginary line connecting the center of the arc of the first color filter disposed in the second unit pixel and a center of the first color filter disposed in the second unit pixel is defined as a second center line, an angle between an imaginary line extending along the first center line and an imaginary line extending along the second center line is about 90 degrees or about 180 degrees.

12. The display device of claim 4, wherein
a third unit pixel adjacent to the first unit pixel in another direction intersecting the one direction comprises a first pixel area, a second pixel area, a third pixel area and a fourth pixel area,
a color filter part disposed in the third unit pixel comprises a first color filter, a second color filter and a third color filter having a substantially fan shape, and
the color filter part of the third unit pixel has a same shape as the color filter part of the first unit pixel in plan view.

13. The display device of claim 1, further comprising:
a pixel defining layer disposed on the pixel electrode and defining a drilling area and a light emitting area overlapping the pixel electrode.

14. The display device of claim 13, further comprising:
a common voltage line disposed on the substrate; and
a common connection electrode disposed on the common voltage line and electrically connected to the common voltage line through a contact hole of an insulating layer in the drilling area.

15. The display device of claim 14, wherein the light emitting layer has a drilling hole penetrating the light emitting layer in the drilling area.

16. The display device of claim 15, wherein the common electrode is electrically connected to the common connection electrode through the drilling hole of the light emitting layer.

17. The display device of claim 15, wherein the drilling hole is disposed in an intersection area of the common voltage line and the common connection electrode.

18. The display device of claim 14, wherein
the common connection electrode extends in a direction, and
the common voltage line extends in another direction intersecting the direction.

19. The display device of claim 18, wherein the first unit pixel is disposed in any one of unit areas surrounded and defined by a plurality of common voltage lines and a plurality of common connection electrodes.

20. The display device of claim 1, wherein each of the first pixel area, the second pixel area, the third pixel area and the fourth pixel area has a substantially triangular shape.

21. The display device of claim 1, wherein at least one of the first color filter, the second color filter, and the third color filter has a central angle of about 120 degrees.

22. The display device of claim 1, wherein the pixel electrode of the first unit pixel comprises:
a first pixel electrode corresponding to the first color filter and having a substantially fan shape;
a second pixel electrode corresponding to the second color filter and having a substantially fan shape; and
a third pixel electrode corresponding to the third color filter and having a substantially fan shape.

23. The display device of claim 1, further comprising:
a light transmitting part disposed between the common electrode and the color filter part.

24. The display device of claim 23, wherein the light transmitting part comprises:
a first light transmitting part corresponding to the first color filter and having a substantially fan shape;
a second light transmitting part corresponding to the second color filter and having a substantially fan shape; and
a third light transmitting part corresponding to the third color filter and having a substantially fan shape.

25. The display device of claim 1, wherein
the first color filter is a color filter which transmits blue light,
the second color filter is a color filter which transmits green light, and
the third color filter is a blue color filter which transmits red light.
